(19) United States
(12) Patent Application Publication
(10) Pub. No.: US 2026/0282507 A1
(43) Pub. Date: Sep. 17, 2026

(54) SEMICONDUCTOR STRUCTURE AND METHOD OF FORMING THEREOF

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 19/081,930

(22) Filed: Mar. 17, 2025

(51) Int. Cl. H10D 84/01; H10D 64/23; H10D 84/83

(52) U.S. Cl. CPC H10D 84/0149; H10D 64/254; H10D 84/013; H10D 84/832

(57) ABSTRACT

A method includes a number of operations. A front-side source/drain contact is formed to electrically couple to a first source/drain feature. A front-side metal silicide layer with a curved profile is formed between the first source/drain feature and the front-side source/drain contact, wherein the front-side metal silicide layer vertically extends a first extension depth from a top surface of the first source/drain feature to a bottom of the front-side metal silicide layer. A backside source/drain contact is formed to electrically couple to a second source/drain feature. A backside metal silicide layer is formed between the second source/drain feature and the backside source/drain contact, wherein the backside metal silicide layer vertically extends a second extension depth from a bottom surface of the second source/drain feature to a top of the backside metal silicide layer, and wherein the second extension depth is less than the first extension depth.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 19G are top views and cross-sectional views of intermediate stages in the manufacturing of GAA-FETs, in accordance with some embodiments.

FIGS. 20A and 20B illustrate cross-sectional views of a semiconductor structure, in accordance with some embodiments.

FIGS. 21A and 21B illustrate cross-sectional views of a semiconductor structure, in accordance with some embodiments.

FIGS. 22A through 22C illustrate cross-sectional views of a semiconductor structure, in accordance with some embodiments.

FIGS. 23A through 23E illustrate top views and cross-sectional views a semiconductor structure, in accordance with some embodiments.

FIGS. 24A and 24B illustrate cross-sectional views of a semiconductor structure, in accordance with some embodiments.

FIGS. 25A and 25B illustrate cross-sectional views of a semiconductor structure, in accordance with some embodiments.

FIGS. 26A through 26C illustrate cross-sectional views of a semiconductor structure, in accordance with some embodiments.

FIGS. 27A through 27E illustrate top views and cross-sectional views a semiconductor structure, in accordance with some embodiments.

FIGS. 28A and 28B illustrate cross-sectional views of a semiconductor structure, in accordance with some embodiments.

FIGS. 29A and 29B illustrate cross-sectional views of a semiconductor structure, in accordance with some embodiments.

FIGS. 30A through 30C illustrate cross-sectional views of a semiconductor structure, in accordance with some embodiments.

FIGS. 31A through 31E illustrate top views and cross-sectional views a semiconductor structure, in accordance with some embodiments.

FIGS. 32A and 32B illustrate cross-sectional views of a semiconductor structure, in accordance with some embodiments.

FIGS. 33A and 33B illustrate cross-sectional views of a semiconductor structure, in accordance with some embodiments.

FIGS. 34A through 34C illustrate cross-sectional views of a semiconductor structure, in accordance with some embodiments.

FIGS. 35A and 35B illustrate cross-sectional views of a semiconductor structure, in accordance with some embodiments.

FIGS. 36A and 36B illustrate cross-sectional views of a semiconductor structure, in accordance with some embodiments.

FIG. 37 illustrates a schematic view of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to integrated circuit (IC) structures and methods of forming the same, and more particularly to fabricating gate-all-around (GAA) transistors, planar transistors, and/or fin field effect transistors (FinFET). It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

Various embodiments relate to a semiconductor structure with backside source/drain contacts. The use of the backside source/drain contacts is to increase parts of metal layers to the backside of the wafer to reduce the routing loading as well as circuit density. The less metal tracks in same area also benefit the metal conductor RC performance. The power conductors at the backside of the wafer may have more robustness power mesh in cell region. In some embodiments, front-side source/drain contacts with extension depths into the source/drain regions of the semiconductor structure for RC reduction as well as current crowding reduction. In some embodiments, backside source/drain contacts land on an extra epitaxial growth with high dopant species for source/drain regions for RC reduction. In one or more embodiments of the present disclosure, the extension depth of the front-side source/drain contact into the source/drain region is greater than the extension depth of the backside source/drain contact into the source/drain region. In some embodiments, the extension depth of the front-side and backside source/drain contacts into the source/drain region with different conductive type may be different. In some embodiments, the backside source/drain contact extends through the bottom dielectric under the source/drain region. In some embodiments, the backside source/drain contact may have different widths at different heights.

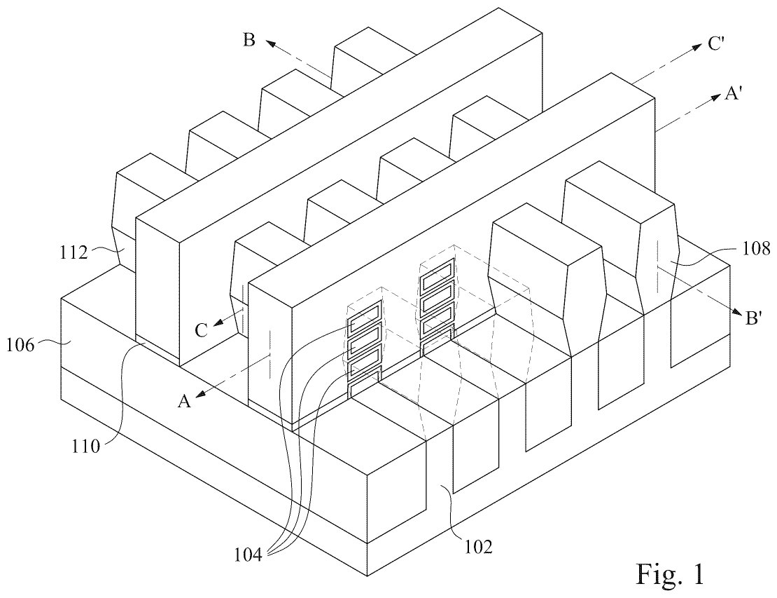

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions for the GAA-FETs. The nanostructures 104 may include p-type nanostructures, n-type nanostructures, or a combination thereof. Isolation regions 106 are disposed between adjacent fins 102, which may protrude above and from between neighboring isolation regions 106. Although the isolation regions 106 are described and illustrated as being separate from the substrate 100, as used herein, the term “substrate” may refer to the semiconductor substrate alone or a combination of the semiconductor substrate and the isolation regions. Additionally, although a bottom portion of the fins 102 is illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction that is, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

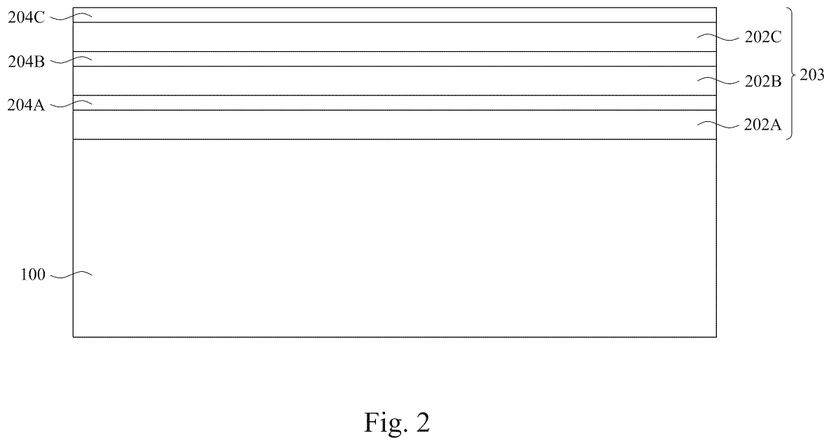

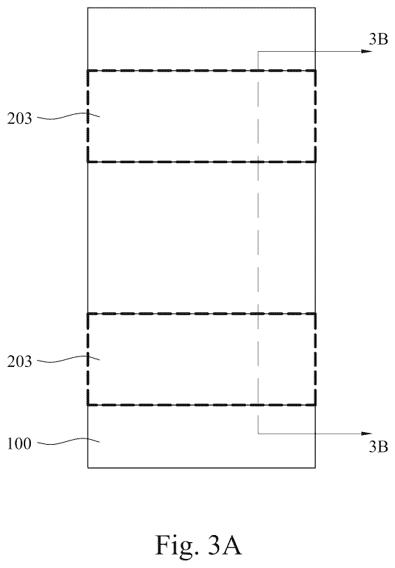

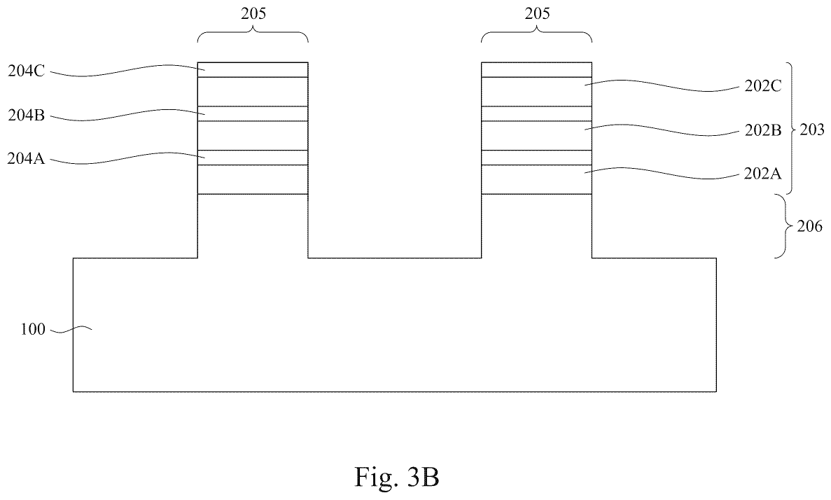

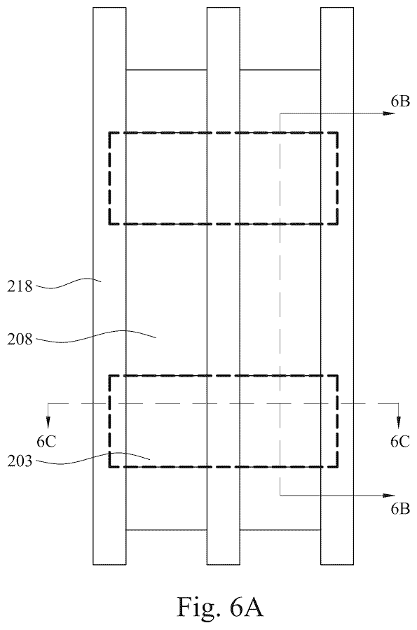

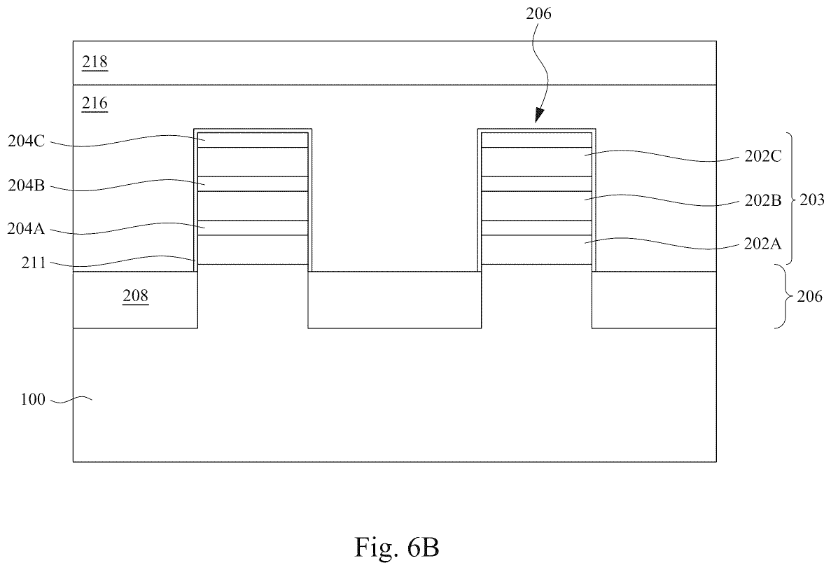

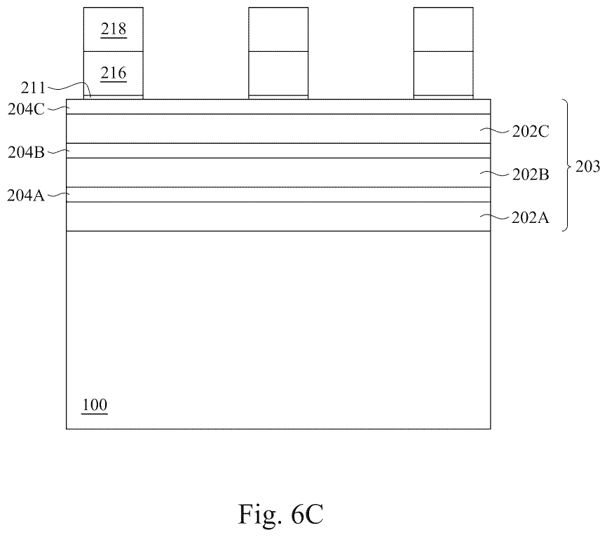

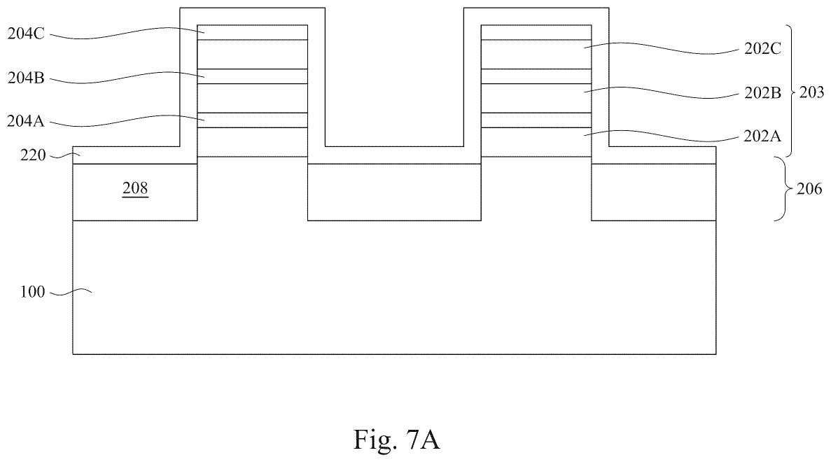

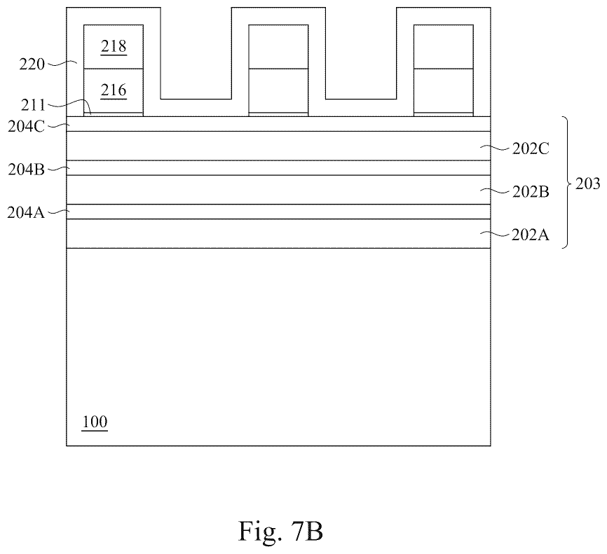

FIGS. 2 through 18C are top views and cross-sectional views of intermediate stages in the manufacturing of GAA-FETs, in accordance with some embodiments. FIGS. 3A, 4A, 6A, 8A, 17A, 17D, 18A and 18C illustrate schematic top views of intermediate stages in the manufacturing of GAA-FETs, in accordance with some embodiments. FIGS. 2, 3B, 4B, 4C, 5, 6B, 13A, 14A, 15A, 16A, 17B and 18B illustrate reference cross-section A-A′ illustrated in FIG. 1 that extends through a gate region along a longitudinal axis of the gate region. FIGS. 6B, 7B, 8C, 9B, 10B, 11B, 11C, 12B, 12C, 12D, 13B, 14B, 15B, 16B and 17C illustrate cross-sectional views of reference cross-section B-B′ illustrated in FIG. 1 that extends through a fin along a longitudinal axis of the fin. FIGS. 7A, 8B, 9A, 10A, 11A, 12A, 13C and 17D illustrate reference cross-section C-C′ illustrated in FIG. 1 that extends through source/drain regions along the longitudinal direction of the gate region.

Reference is made to FIG. 2. FIG. 2 illustrates forming a multi-layer stack 201 over a substrate 100, in accordance with some embodiments.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

Reference is made to FIGS. 3A and 3B. FIGS. 3A and 3B illustrate forming fin structures 206 and nanostructures 203, in accordance with some embodiments. FIG. 3B illustrates a cross-sectional view along the cross-section 3B-3B in FIG. 3A.

As illustrated in FIGS. 3A and 3B, fin structures 206 are formed in the substrate 100 and nanostructures 203 are formed in the multi-layer stack 201, in accordance with some embodiments. Each fin structure 206 and corresponding nanostructures 203 directly above the fin structure 206 can be collectively referred to as an active region 205. In some embodiments, the nanostructures 203 and the fin structures 206 may be formed in the multi-layer stack 201 and the substrate 100, respectively, by etching trenches in the multi-layer stack 201 and the substrate 100. The fin structure 206 can be referred to as base regions of the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 is illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

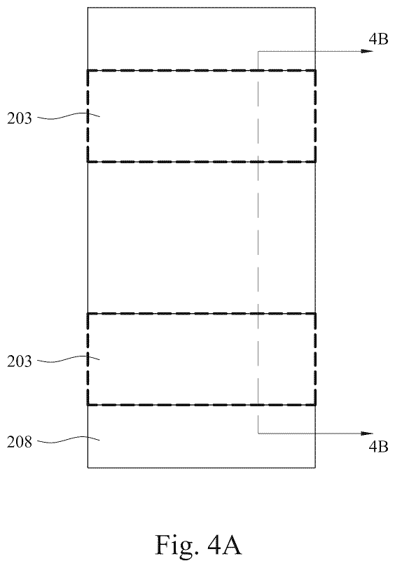

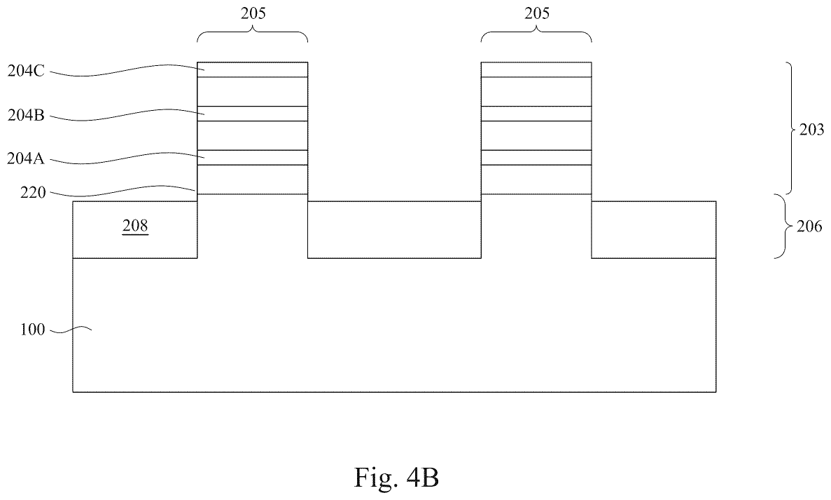

Reference is made to FIGS. 4A and 4B. FIGS. 4A and 4B illustrate formation of shallow trench isolation (STI) regions 208, in accordance with some embodiments. FIG. 4B illustrates a cross-sectional view along the cross-section 4B-4B in FIG. 4A.

In FIGS. 4A and 4B, shallow trench isolation (STI) regions 208 are formed adjacent to the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

FIG. 4C illustrates a cross-sectional view formation of the STI regions 208, in accordance with some embodiments. In FIG. 4C, top surfaces of the STI regions 208 are non-planar. In other words, the top surfaces of the STI regions 208 are not at the same level. Interfaces between the STI regions 208 and the contact etch stop layers subsequently formed over the STI region 208 may thus be non-planar, in accordance with some embodiments.

The process described above with respect to FIGS. 2 through 4C is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in-situ doped during growth, which may obviate prior and/or subsequent implantations, although in-situ and implantation doping may be used together.

Further in FIGS. 4A through 4C, appropriate wells (not separately illustrated) may be formed in the fin structures 206 and/or the nanostructures 203. In some embodiments, the appropriate wells are formed prior to formation of the nanostructures 203 and/or semiconductor layers 204. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in-situ doped during growth, which may obviate the implantations, although in-situ and implantation doping may be used together.

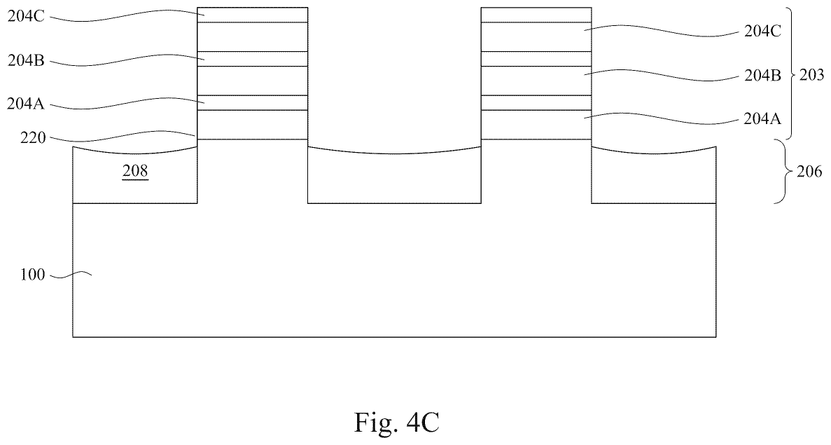

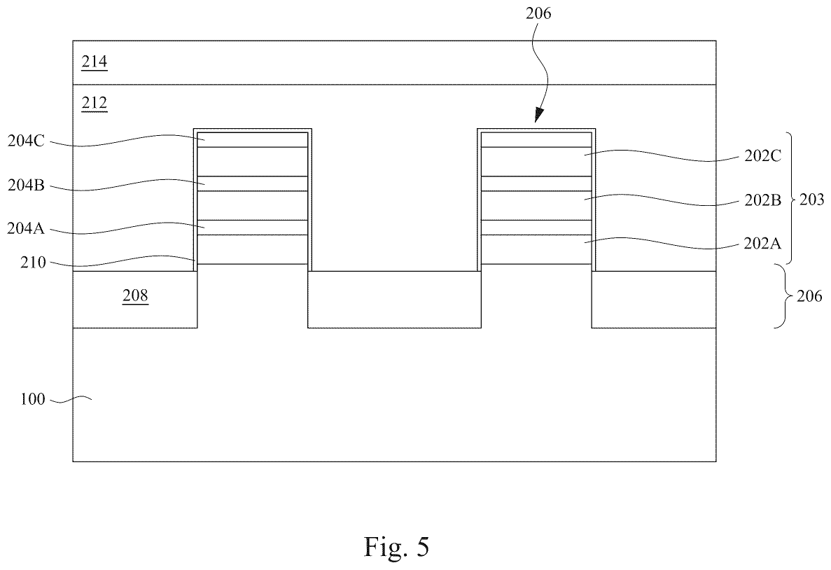

Reference is made to FIG. 5. FIG. 5 illustrates formation of a dummy gate structure, in accordance with some embodiments.

In FIG. 5, dummy dielectric layers 210 are formed on the fin structures 206 and/or the nanostructures 203 in the regions R1 and R2. The dummy dielectric layers 210 may be, for example, silicon oxide, silicon nitride, a combination thereof, or the like, and may be deposited or thermally grown according to acceptable techniques. A dummy gate layer 212 is formed over the dummy dielectric layers 210, and a mask layer 214 is formed over the dummy gate layer 212. The dummy gate layer 212 may be deposited over the dummy dielectric layers 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

Reference is made to FIGS. 6A through 6C. FIGS. 6A through 6C illustrate patterning the mask layer 214 and the dummy gate layer 212, in accordance with some embodiments. FIG. 6B illustrates a cross-sectional view along the cross-section 6B-6B in FIG. 6A. FIG. 6C illustrates a cross-sectional view along the cross-section 6C-6C in FIG. 6A.

In FIGS. 6A through 6C, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

Reference is made to FIGS. 7A and 7B. FIGS. 7A and 7B illustrate forming one or more spacer layers, in accordance with some embodiments.

In FIGS. 7A and 7B, a spacer layer 220 is formed over the structures illustrated in FIGS. 6A and 6B, respectively. The spacer layer 220 will be subsequently patterned to act as spacers for forming self-aligned source/drain regions. In FIGS. 7A and 7B, the spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The spacer layer 220 may be formed of silicon oxide, silicon nitride, silicon oxynitride, or the like, using techniques such as thermal oxidation or deposited by CVD, ALD, or the like. In some embodiments, one or more spacer layers can be formed over the spacer layer 220 and be formed of a material having a different etch rate than the material of the spacer layer 220, such as silicon oxide, silicon nitride, silicon oxynitride, or the like, and may be deposited by CVD, ALD, or the like. (2^{nd} spacer)

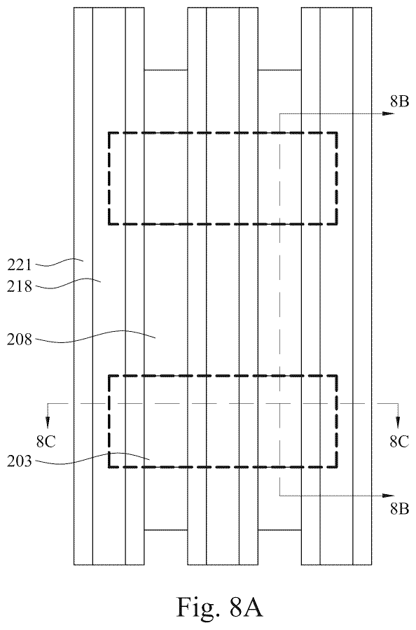

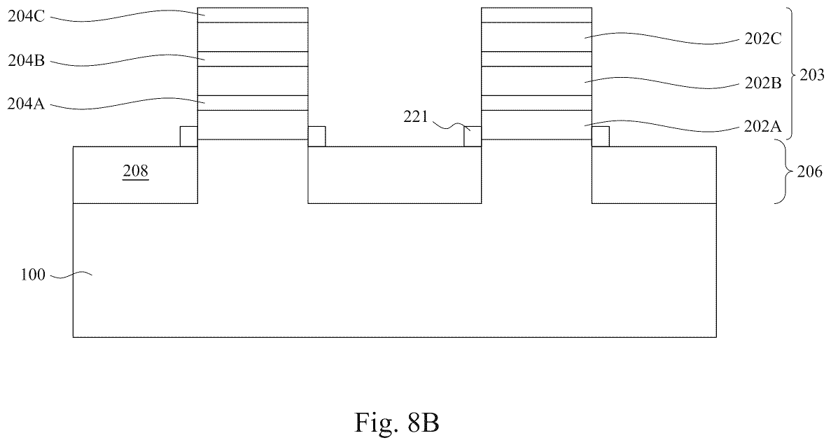

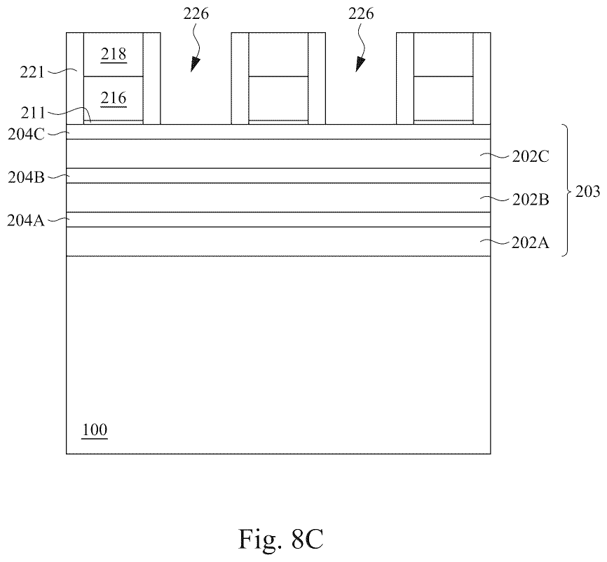

Reference is made to FIGS. 8A through 8C. FIGS. 8A through 8C illustrate formation gate spacers, in accordance with some embodiments. FIG. 8B illustrates a cross-sectional view along the cross-section 8B-8B in FIG. 8A. FIG. 8C illustrates a cross-sectional view along the cross-section 8C-8C in FIG. 8A.

In FIGS. 8A through 8B, the spacer layer 220 is etched to form spacers 221. As will be discussed in greater detail below, the spacers 221 act to self-align subsequently formed source and drain regions (collectively referred to as source/drain regions), as well as to protect sidewalls of the fin structures 206 and/or nanostructures 203 during subsequent processing. The spacers 221 may act as gate spacers. The spacer layer 220 may be etched using a suitable etching process, such as an isotropic etching process (e.g., a wet etching process), an anisotropic etching process (e.g., a dry etching process), or the like. As illustrated in FIG. 8B, the spacers 221 are disposed on sidewalls of the fin structures 206 and/or nanostructures 203. In some embodiments, the spacers 221 only partially remain on sidewalls of the fin structures 206. In some embodiments, no spacer remains on sidewalls of the fin structures 206.

In some embodiments, the spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts. In some embodiments, a horizontal thickness of the spacers 221 ranges from about 3 nm to about 12 nm.

The above disclosure generally describes a process of forming spacers. Other processes and sequences may be used. For example, fewer or additional spacers may be utilized, different sequence of steps may be utilized, additional spacers may be formed and removed, and/or the like.

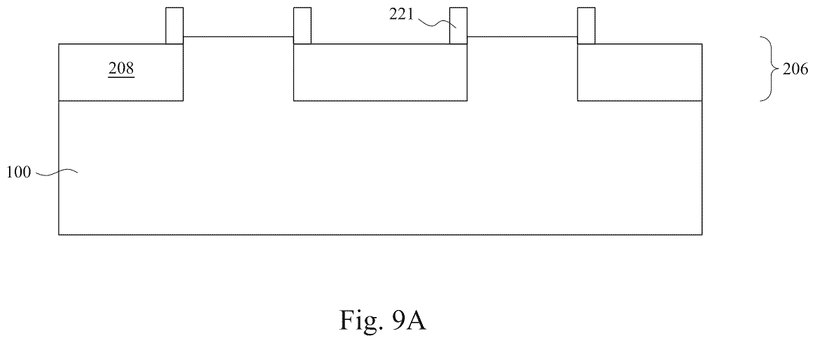

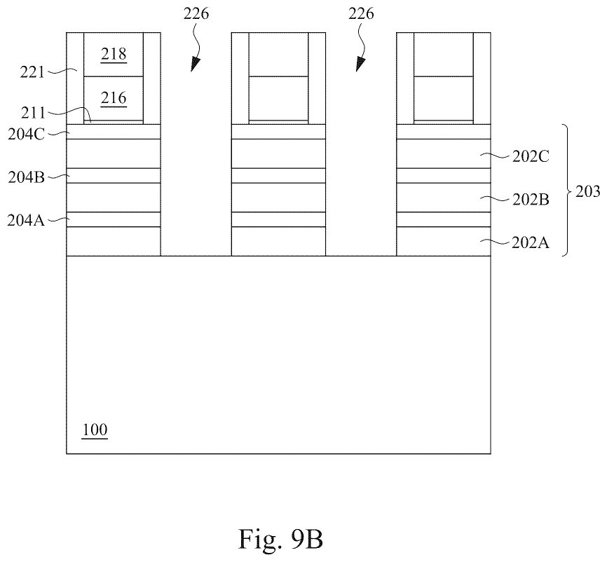

Reference is made to FIGS. 9A and 9B. FIGS. 9A and 9B illustrates forming source/drain recesses 226, in accordance with some embodiments.

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

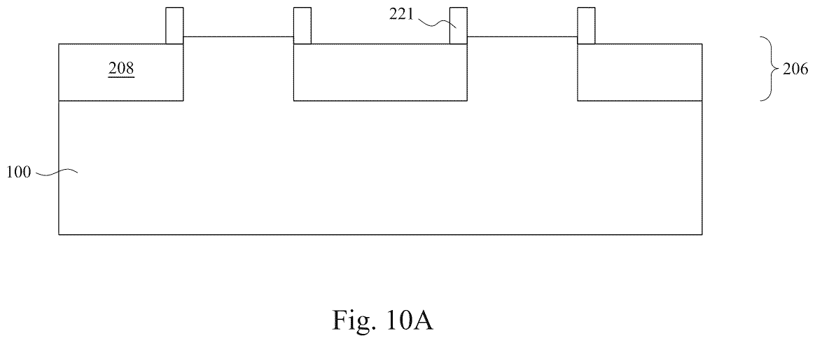

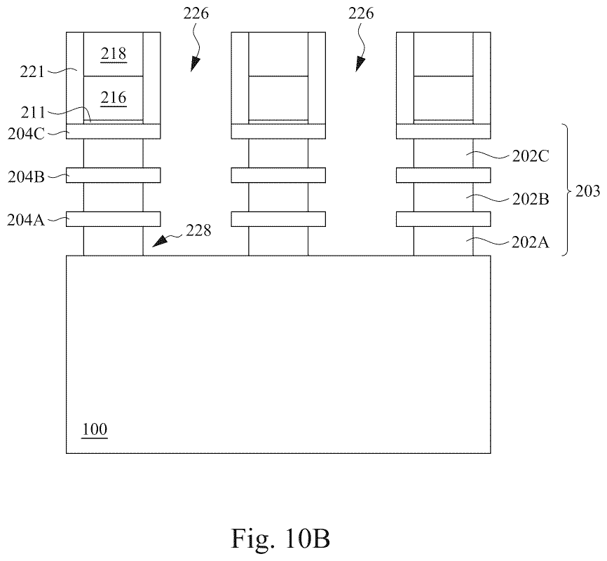

Reference is made to FIGS. 10A and 10B. FIGS. 10A and 10B illustrate laterally recessing the nanostructure of the nanostructures 204, in accordance with some embodiments.

In FIGS. 10A and 10B, portions of sidewalls of the layers of the multi-layer stack 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

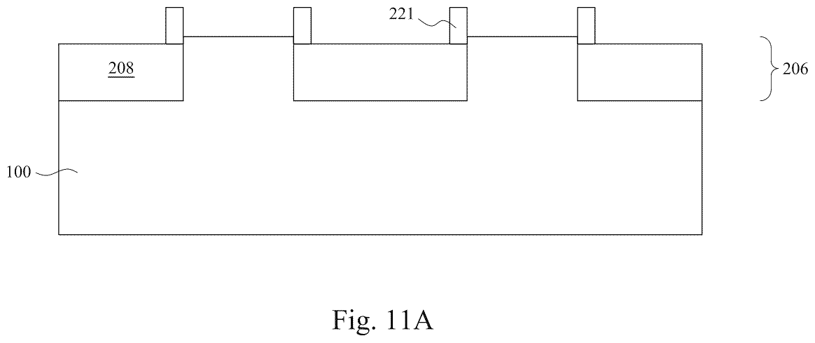

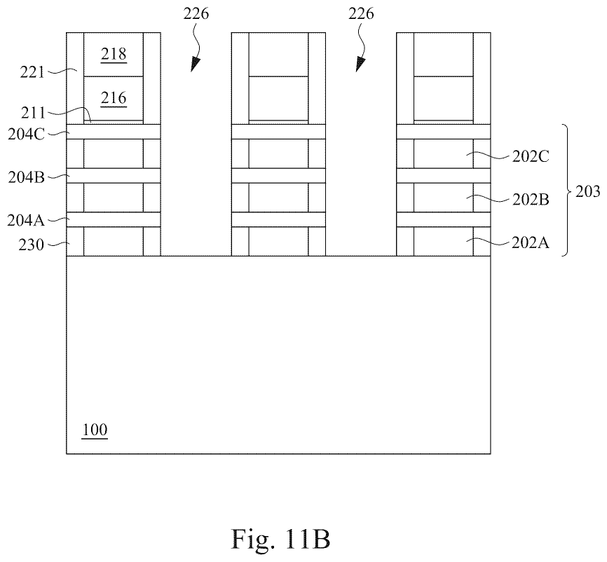

Reference is made to FIGS. 11A and 11B. FIGS. 11A and 11B illustrates forming inner spacers 230, in accordance with some embodiments.

In FIGS. 11A and 11B, inner spacers 230 are formed in the sidewall recess 228. The inner spacers 230 may be formed by depositing an inner spacer layer (not separately illustrated) over the structures illustrated in FIGS. 10A and 10B. The inner spacers 230 act as isolation features between subsequently formed source/drain regions and gate structure. As will be discussed in greater detail below, source/drain regions will be formed in the recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

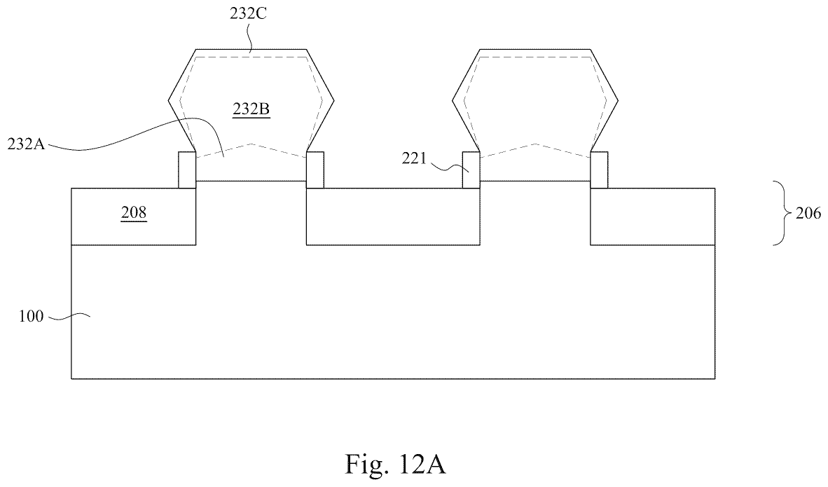

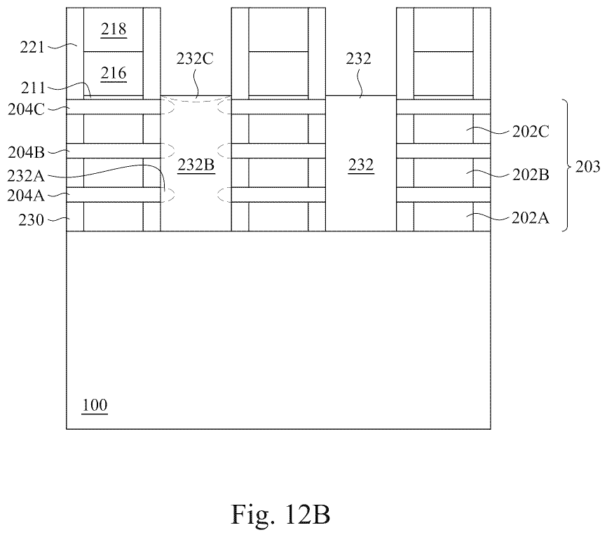

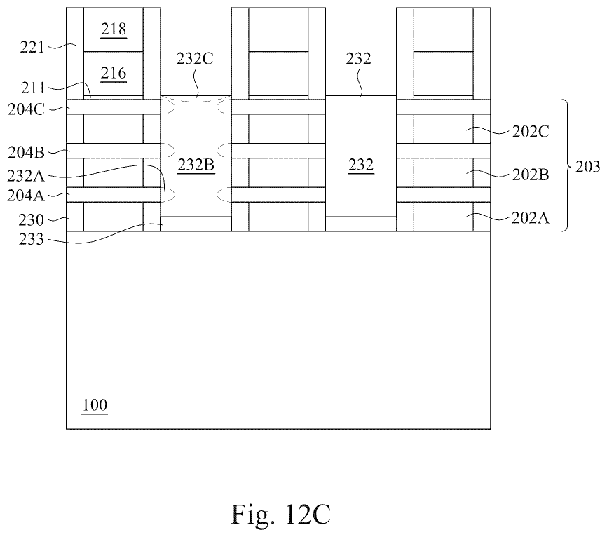

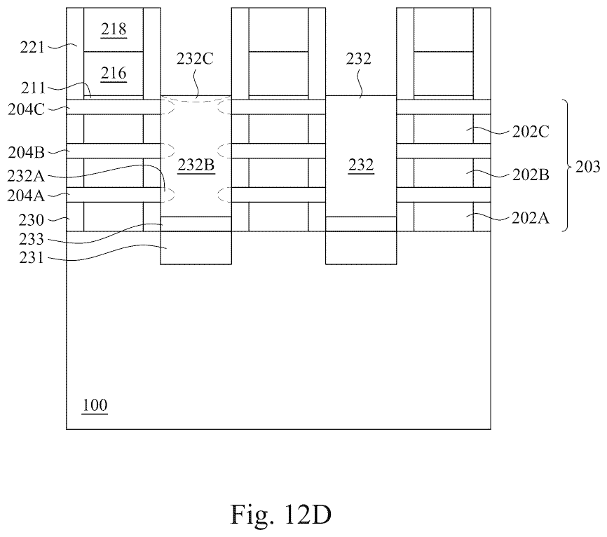

Moreover, although the outer sidewalls of the inner spacers 230 are illustrated as being straight in FIG. 11B, the outer sidewalls of the inner spacers 230 may be concave or convex. As an example, FIG. 11C illustrates an embodiment in which sidewalls of the first nanostructures 202 are concave, outer sidewalls of the inner spacers 230 are concave, and the inner spacers are recessed from sidewalls of the second nanostructures 204. The inner spacer layer may be etched by an anisotropic etching process, such as RIE, NBE, or the like. The inner spacers 230 may be used to prevent damage to subsequently formed source/drain regions (such as the epitaxial source/drain regions 232, discussed below with respect to FIGS. 12A-12C) by subsequent etching processes, such as etching processes used to form gate structures. In some embodiments, a horizontal thickness of one of the inner spacers 230 ranges from about 2 nm to about 10 nm. In some embodiments, the dielectric material of the gate spacers 221 is different from the dielectric material of the inner spacers 230. In some embodiments, the horizontal thickness of one of the gate spacers 221 is greater than the horizontal thickness of one of the inner spacers 230, and the horizontal thickness difference between one of the gate spacers 221 and one of the inner spacers 230 ranges from about 0.5 nm to about 5 nm.

Reference is made to FIGS. 12A through 12D. FIGS. 12A through 12D illustrate formation of source/drain epitaxial source/drain regions 232, in accordance with some embodiments.

FIG. 12A illustrate reference cross-section C-C′ illustrated in FIG. 1 that extends through source/drain regions along the longitudinal direction of the gate region. FIG. 12B illustrates cross-sectional views of reference cross-section B-B′ illustrated in FIG. 1 that extends through a fin along a longitudinal axis of the fin. In FIGS. 12A and 12B, epitaxial source/drain regions 232 are formed in the source/drain recesses 226.

In some embodiments, the source/drain regions 232 may exert stress on the second nanostructures 204, thereby improving device performance. As illustrated in FIG. 12B, the epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gates 212, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration within a range from about 1×10¹⁷ atoms/cm³ to about 1×10²² atoms/cm³. The n-type and/or p-type impurities for source/drain regions may be any of the impurities previously discussed. In some embodiments, the epitaxial source/drain regions 232 may be in-situ doped during growth. For example, in some embodiments, an n-type source/drain region 232 may have phosphorus doping concentration within a range from about 2×10¹⁹ atoms/cm³ and about 3×10²¹ atoms/cm³. In some embodiments, a p-type source/drain region 232 may have boron doping concentration within a range from about 1×10¹⁹ atoms/cm³ and about 6×10²⁰ atoms/cm³.

As a result of the epitaxy processes used to form the epitaxial source/drain regions 232, upper surfaces of the epitaxial source/drain regions 232 have facets which expand laterally outward beyond sidewalls of the nanostructures 203. As illustrated in FIG. 12A, adjacent epitaxial source/drain regions 232 remain separated after the epitaxy process is completed. In some embodiments, facets of the upper surfaces of the epitaxial source/drain regions 232 cause adjacent epitaxial source/drain regions 232 to merge. In FIG. 12A, the first spacers 221, 223 may be formed to a top surface of the STI regions 208 thereby blocking the lateral epitaxial growth. In some embodiments, the spacer etch used to form the first spacers 221, 223 may be adjusted to remove the spacer material to allow the epitaxially grown region to extend to the surface of the STI region 208.

In one or more embodiments of the present disclosure, the epitaxial source/drain regions 232 may include one or more semiconductor material layers. For example, the epitaxial source/drain regions 232 may include a first semiconductor material layer 232A, a second semiconductor material layer 232B, and a third semiconductor material layer 232C, which are distinguished in FIG. 12B by using dash-lines. Any number of semiconductor material layers may be used for the epitaxial source/drain regions 232. Each of the first semiconductor material layer 232A, the second semiconductor material layer 232B, and the third semiconductor material layer 232C may be formed of different semiconductor materials and may be doped to different dopant concentrations. In embodiments in which the epitaxial source/drain regions 232 include three semiconductor material layers, the first semiconductor material layer 232A may be deposited over surfaces of the nanostructures 204 and the substrate 100 exposed from the source/drain recesses 226, the second semiconductor material layer 232B may be deposited over the first semiconductor material layer 232A, and the third semiconductor material layer 232C may be deposited over the second semiconductor material layer 232B.

In some embodiments, the epitaxial source/drain regions 232 may be formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes. The epitaxial source/drain regions 232, the nanostructures 202, 204, and/or the fin structure 206 may be implanted with impurities, similar to the process previously described for forming LDD regions, followed by an anneal. In some embodiments, the epitaxial source/drain regions 232 are in-situ doped or undoped during the epi process. When the epitaxial source/drain regions 232 are undoped, they may be doped in a subsequent process. The doping may be achieved by an ion implantation process, plasma immersion ion implantation (PIII) process, gas and/or solid source diffusion process, or other suitable process. Afterwards, the epitaxial source/drain regions 232 may be exposed further to annealing processes, such as a rapid thermal annealing process.

In some embodiments, as illustrated in FIG. 12B, the source/drain regions 232 have portions embedded in the substrate 100.

FIG. 12C illustrates formation of source/drain regions 232, in accordance with some embodiments. FIG. 12C illustrates cross-sectional views of reference cross-section B-B′ illustrated in FIG. 1 that extends through a fin along a longitudinal axis of the fin.

In some embodiments, before forming the first semiconductor layers 232A of the source/drain regions 232, a plurality of dielectric layers 233 may be formed in the source/drain recesses 226. The dielectric layer 233 can be interchangeably referred to a dielectric barrier layer or a leakage barrier for reducing leakage current. In some embodiments, the dielectric layer 233 can be made of a different material than the inner spacer 230. In some embodiments, the dielectric layer 233 can be formed during a same process as forming the inner spacer 230, in which the material to form the inner spacer 230 can be remained at the bottom of the source/drain recesses 226 to act as the dielectric layer 233. In some embodiments, the dielectric layer 233 is made of an oxide-containing material (e.g., SiO₂), a nitrogen-containing material (e.g., SiON, SiN, Si₃N₄), a carbon-containing material (e.g., SiOC, SIOCN), a high-k dielectric layer (e.g., HfO, AlO), the like, or combinations thereof. In some embodiments, the dielectric layer 233 may be made of a material having a dielectric constant greater than about 7.9 (e.g., high dielectric constant (high-k) material). For example, the dielectric layer 233 may be made of a high dielectric constant (high-k) material, such as hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. In some embodiments, one of the dielectric layers 233 is a single dielectric layer or multiple dielectric layers and has a vertically thickness in a range from about 1 nm to about 20 nm.

In some embodiments, before forming the first semiconductor layers 232A of the source/drain regions 232, un-doped semiconductor layers 231 are formed in the source/drain recesses 226. For example, material of the un-doped semiconductor layers 231 can include un-doped silicon. In some embodiments, material of the un-doped semiconductor layers 231 can include material different from the substrate 100. For example, the material of the un-doped semiconductor layers 231 may include un-doped SiGe. In some embodiments, the un-doped semiconductor layers 231 are epitaxially grown. In some embodiments, one of the un-doped semiconductor layers 231 extends a vertical depth into the substrate 100 within a range from about 10 nm to about 50 nm.

FIG. 12D illustrates formation of source/drain regions 232, in accordance with some embodiments. FIG. 12D illustrates cross-sectional views of reference cross-section B-B′ illustrated in FIG. 1 that extends through a fin along a longitudinal axis of the fin.

As illustrated in FIG. 12D, in some embodiments, before forming the first semiconductor layers 232A of the source/drain regions 232, un-doped semiconductor layers 231 are formed in the source/drain recesses 226. For example, material of the un-doped semiconductor layers 231 can include un-doped silicon. In some embodiments, material of the un-doped semiconductor layers 231 can include material different from the substrate 100 to have etch selectivity relative to the substrate 100. For example, the material of the un-doped semiconductor layers 231 may include un-doped SiGe. The un-doped semiconductor layers 231 with different material from the substrate 100 can thus be used as sacrificial layers for forming backside contacts. In some embodiments, the un-doped semiconductor layers 231 are epitaxially grown. In FIG. 12D, top surfaces of the un-doped semiconductor layers 231 have elevations level with bottom surfaces of the bottommost inner spacers 230. In some embodiments, the top surfaces of the un-doped semiconductor layers 231 are lower than the bottommost nanostructures 204A. In FIG. 12D, the dielectric layers 233 are between the un-doped semiconductor layers 231 and the second semiconductor layers 232B of the source/drain regions 232. In some embodiments, the top surfaces of the dielectric layers 233 are lower than the bottommost nanostructures 204A.

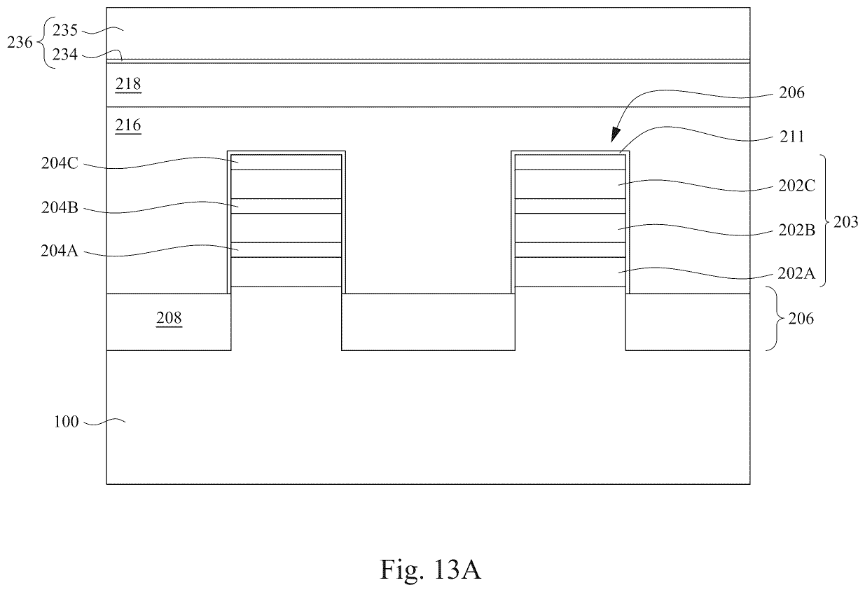

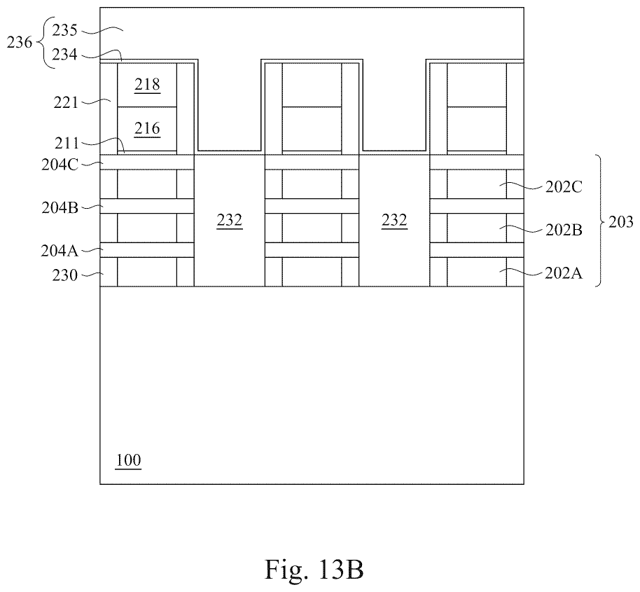

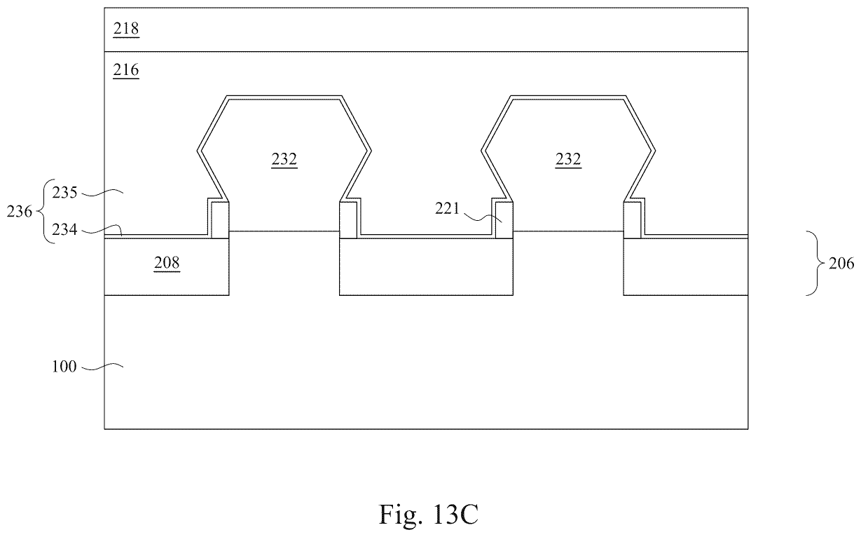

Reference is made to FIGS. 13A through 13C. FIGS. 13A through 13C illustrate forming a dielectric layer 236 including an interlayer dielectric (ILD) layer 235 and a contact etch stop layer (CESL) 234, in accordance with some embodiments.

In FIGS. 13A-13C, an interlayer dielectric (ILD) layer 235 is deposited over the structure illustrated in FIGS. 12A and 12B. The ILD layer 235 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 235 and the epitaxial source/drain regions 232, the masks 214, and the first spacers 221. The CESL 234 may comprise a dielectric material, such as, SiN, SiOₓ, SiCN, SION, SiOCN, Al₂O₃, HfO₂, ZrO₂, HfAlOₓ, and HfSiOₓ, or the like, having a different etch rate than the material of the overlying ILD layer 235.

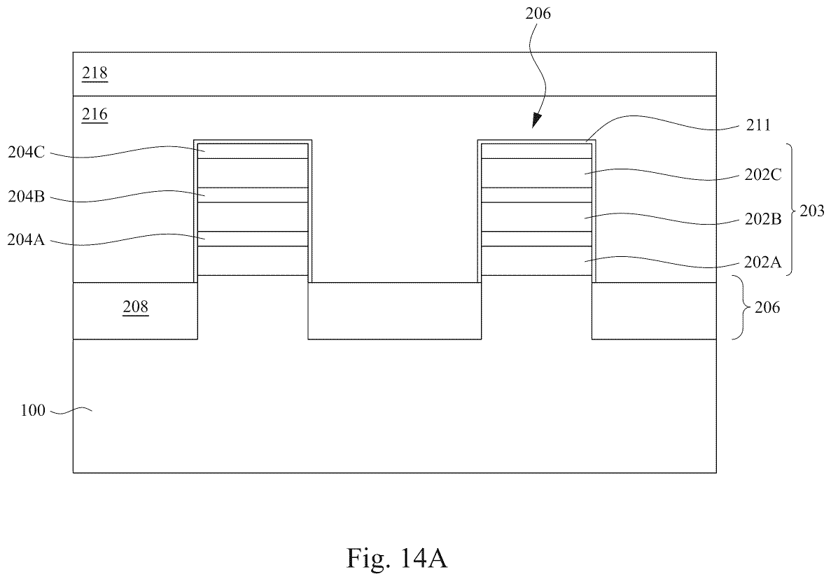

Reference is made to FIGS. 14A and 14B. FIGS. 14A and 14B illustrate performing a planarization process on the structure as illustrated in FIGS. 13A through 13C, in accordance with some embodiments.

In FIGS. 14A and 14B, a planarization process, such as a CMP, may be performed to level the top surface of the ILD layer 235 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 235 are level within process variations. Accordingly, the top surfaces of the dummy gates 212 are exposed through the ILD layer 235. In some embodiments, the masks 218 may remain, in which case the planarization process levels the top surface of the ILD layer 235 with top surface of the masks 218 and the first spacers 221.

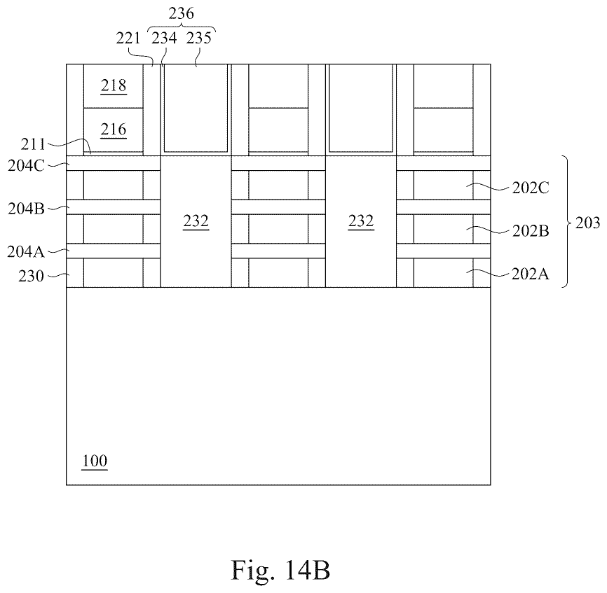

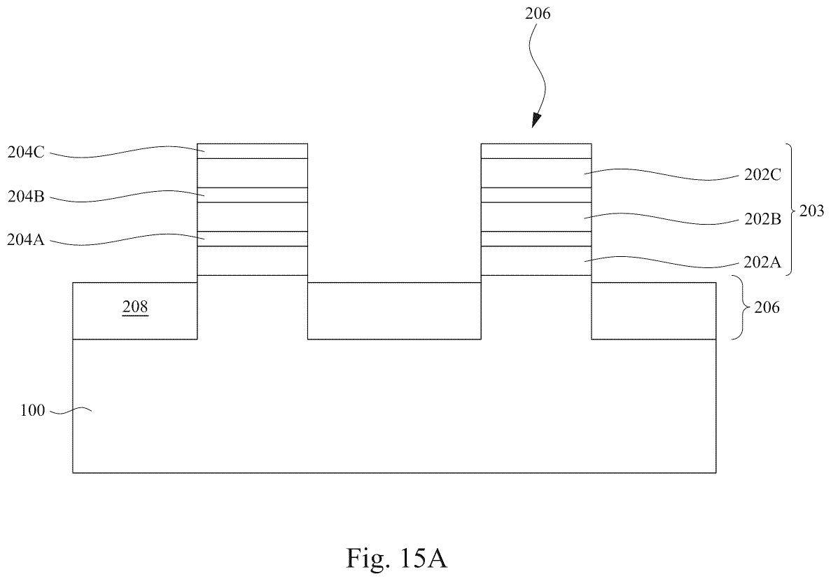

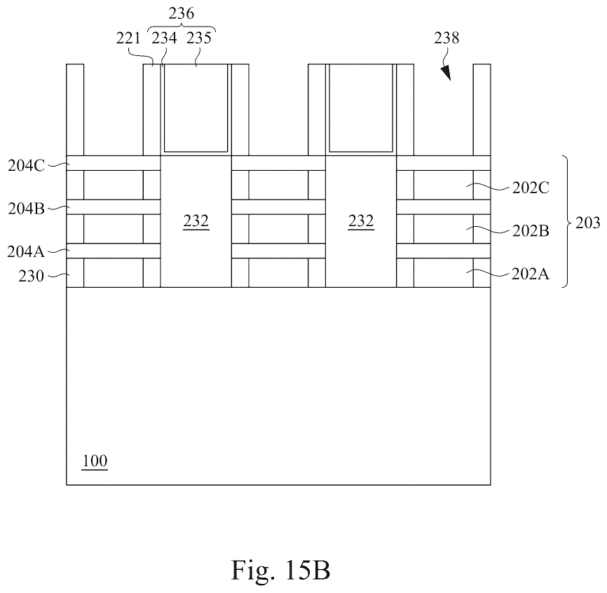

Reference is made to FIGS. 15A and 15B. FIGS. 15A and 15B illustrate removal of dummy gate structures, in accordance with some embodiments.

In FIGS. 15A and 15B, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the protective layer 237 or the first spacers 221. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy gate dielectrics 211 may be used as etch stop layers when the dummy gates 216 are etched. The dummy gate dielectrics 211 may then be removed after the removal of the dummy gates 216.

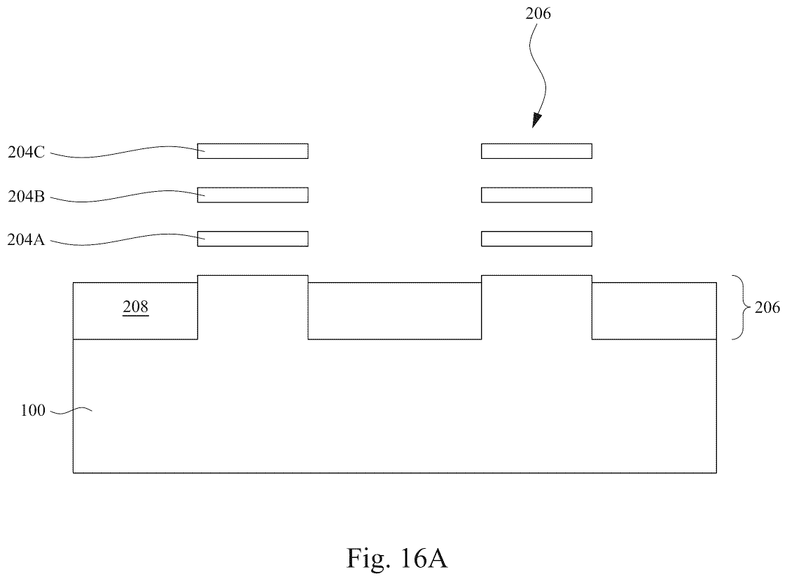

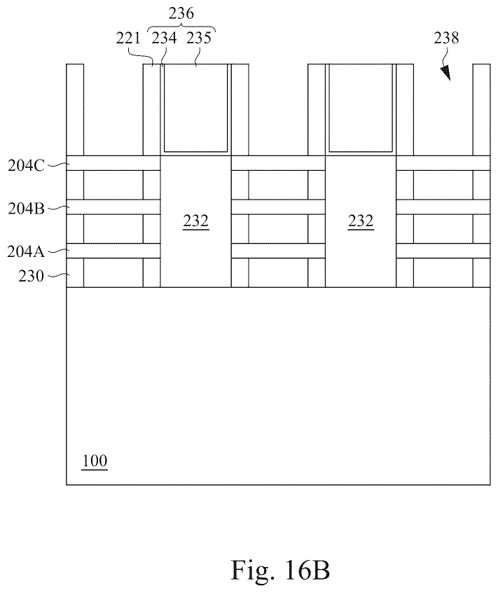

Reference is made to FIGS. 16A and 16B. FIGS. 16A and 16B illustrate removal of the nanostructures 202, in accordance with some embodiments.

In FIGS. 16A and 16B, the first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

In some embodiments, one of the nanostructures 204A-204C of the second nanostructures 204 has a vertical thickness ranging from about 3 nm to about 8 nm. In some embodiments, one of distances between adjacent two of the nanostructures 204A-204C of the second nanostructures 204 ranges from about 4 nm to about 15 nm. In some embodiments, the nanostructures 204 have a vertical sheet pitch in a range from about 7 nm to 23 nm.

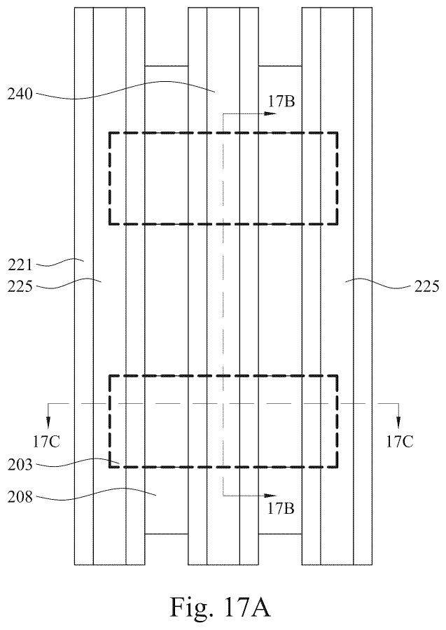

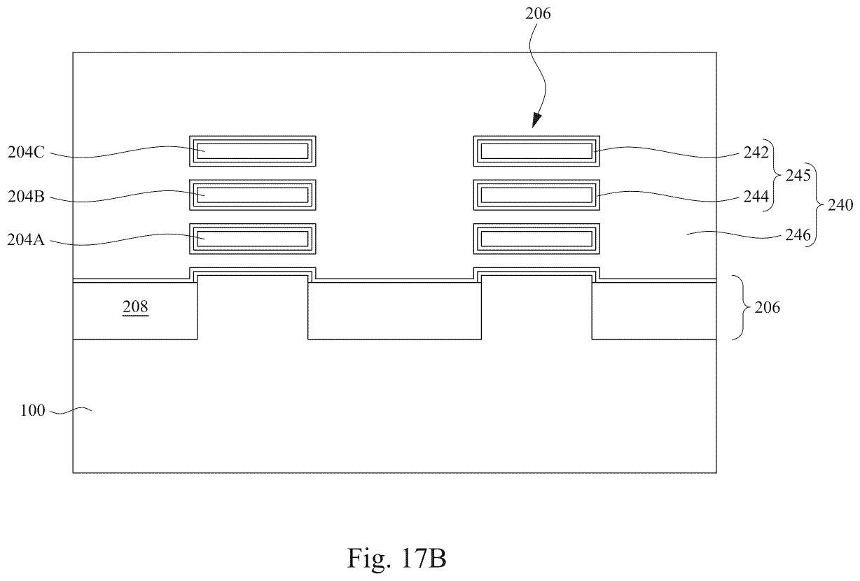

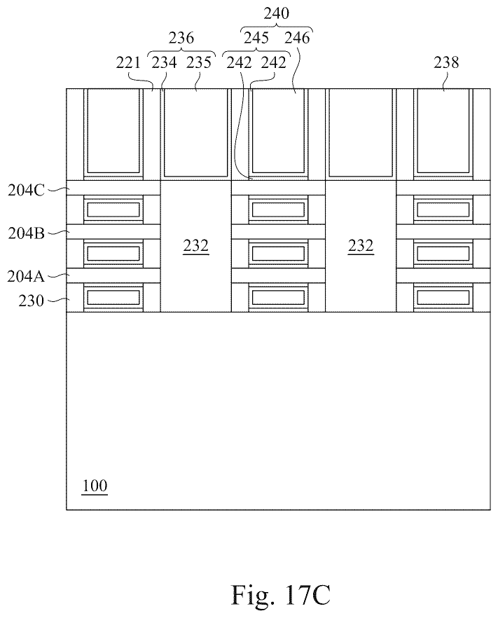

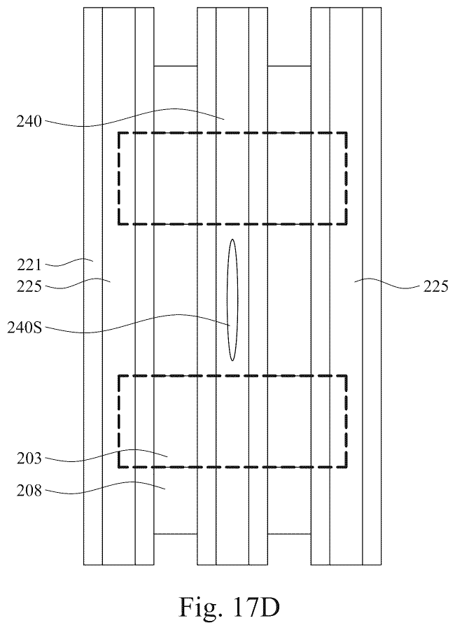

Reference is made to FIGS. 17A through 17C. FIGS. 17A through 17C illustrate formation of replacement gate structures 240, in accordance with some embodiments. FIG. 17B illustrates a cross-sectional view along the cross-section 17B-17B in FIG. 17A. FIG. 17C illustrates a cross-sectional view along the cross-section 17C-17C in FIG. 17A.

In FIGS. 17A through 17C, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. In some embodiments, the interfacial layer 242 and high-k gate dielectric layer 244 can be referred to as a gate dielectric layer 245. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 17A, the high-k/metal gate structure 240 surrounds each of the nanosheets 204, and thus is referred to as a gate of a GAA FET. In some embodiments, a thickness of one of the gate spacer 221 is greater than a thickness of the gate dielectric 244 of the gate structure 240.

In some embodiments, as illustrated in FIG. 17B, the topmost surfaces of the STI regions 208 intermix at an interface between the gate structure 240 and the STI regions 208. In some embodiments, since the top surfaces of the STI regions 208 have different heights (see FIG. 4C), bottommost surfaces of one of the gate structure 240 are not at the same depths. In some embodiments, the topmost surface of one of the gate structures 240 may thus be not planar.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, as illustrated in FIG. 17A, dielectric-based gates 225 can be formed to replace with some dummy gate structures formed of the dummy gate dielectrics 211, the dummy gates 216 and the mask 218 before forming the gate structures 240. In some embodiments, dielectric-based gates 225 can be formed to replace with some gate structures 240 after forming the gate structures 240. Formation of the dielectric-based gates 225 may include, for example, etching the dummy gate dielectrics 211, the dummy gates 216, the mask 218, the nanostructures 203 to form isolation trenches along the lengthwise direction of the gate structures 240, followed by forming dielectric material in the isolation trenches. The dielectric-based gates 225 are common to implement channel layer cuts (or in the oxide definition (OD)) at the end of the nanostructures 203. The dielectric-based gates 225 may referred to as continuous polysilicon on oxide diffusion (OD) edges (CPODEs). In some embodiments, the dielectric-based gate 225 can be made of silicon oxide (SiOₓ), silicon nitride (SiₓN_{y}), silicon oxynitride (SiON), dielectric material(s), other suitable material, or a combination thereof.

FIG. 17D illustrates a top view of forming the gate structures 240, in accordance with some embodiments. In some embodiments, the outermost surface of a gate electrode 240 along the gate direction is non-linear. In other words, an interface between gate spacer 221 and one of the gate structures 240 is curved. In some embodiments, one of the gate structures 240 has a seam 240S in a top view.

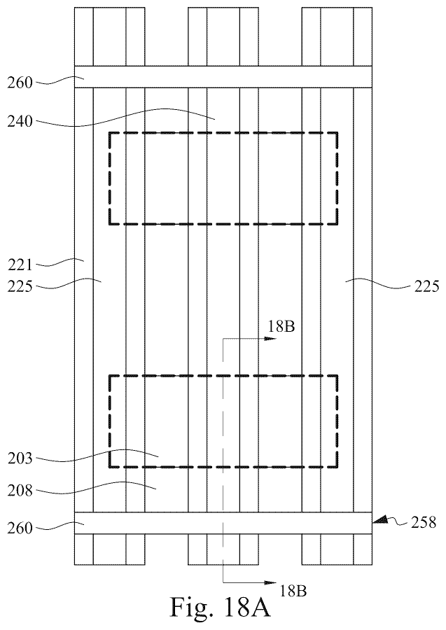

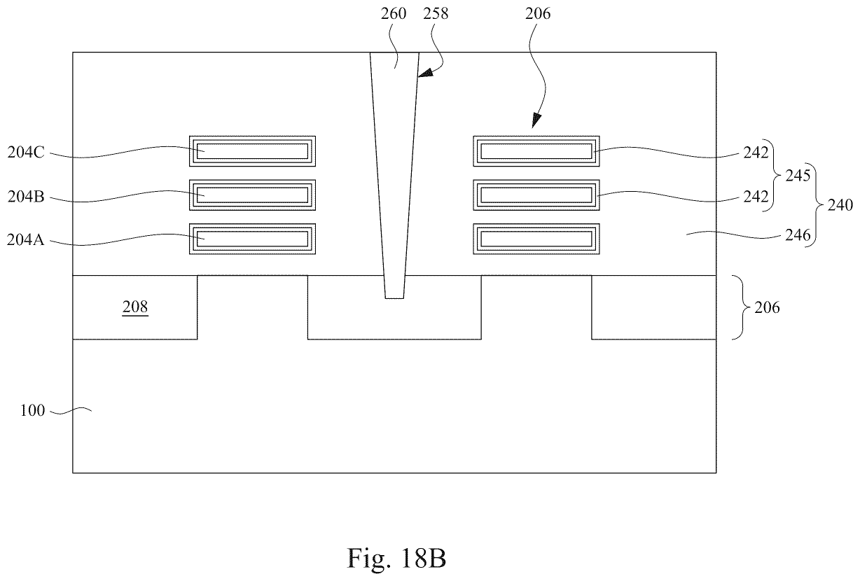

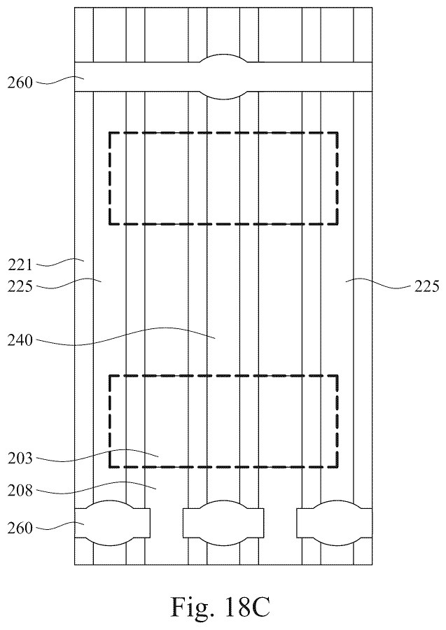

Reference is made to FIGS. 18A and 18B. FIGS. 18A and 18B illustrate formation of gate isolation structures 260, in accordance with some embodiments. FIG. 18B illustrates a cross-sectional view along the cross-section 18B-18B in FIG. 18A, wherein the cross-section 18B-18B is across two stacks of nanostructure 203 on opposite sides of the gate isolation structures 260, one of which is not illustrated in the schematic top view of FIG. 18A.

Formation of the gate isolation structures 260 may include an etching step that can break a continuous gate structure 240 into separate gate structures with no or negligible impact on underlying materials. Such etching step can be referred to as a “gate cut” or “cut metal gate” step. In some embodiments, a patterned mask (e.g., patterned photoresist) is first formed over the substrate 100, except for CMG target regions, and then one or more etching processes are performed on the exposed CMG target regions to form gate cut openings 258 each breaking a continuous gate structure 240 into separate gate structures 240. Afterwards, gate isolation structures 260 are formed in the gate cut openings 258, so as to electrically isolate the separate gate structures 240. Formation of the isolation structures 260 includes, for example, depositing one or more dielectric material overfilling the gate cut openings 258, followed by performing a planarization step (e.g., CMP) to remove excess dielectric material outside the gate cut openings 258. The isolation structures 260 may be formed to replace the gate structures 240 between the adjacent ILD layers 235 (see FIG. 17C).

In some embodiments, the gate isolation structures 260 may be made of a metal oxide material. In some embodiments, the gate isolation structures 260 may be made of a material having a dielectric constant greater than about 9 (e.g., high dielectric constant (high-k) material). For example, the gate isolation structures 260 may be made of a high dielectric constant (high-k) material, such as hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The gate isolation structures 260 may be formed of a homogenous material, or may have a composite structure including more than one layer. In some embodiments, the gate isolation structures 260 may include dielectric liners, which may be formed of, for example, silicon oxide. In some embodiments, the gate isolation structures 260 may include at least two layers such as liner and dielectric bulk fill.

In FIG. 18B, in some embodiments, gate isolation structures 260 extend into the STI regions 208. In some embodiments, a bottommost portion of the gate isolation structures 260 is lower than bottommost portion of gate structure 240. In some embodiments, as shown in FIG. 18B, at least a portion of gate isolation structures 260 extends into the STI regions 208. In some embodiments, at least a portion of gate isolation structures 260 is over and overhangs the STI regions 208.

As illustrated in FIG. 18A, in some embodiments, the gate isolation structures 260 extend along a lengthwise direction of the nanostructures 203. FIG. 18C illustrates formation of gate isolation structures 260 with separated isolation portions. In some embodiments, an interface between one of the gate isolation structures 260 and the gate structure 240 are curved. In other words, the interface between one of the gate isolation structures 260 and the gate structure 240 can be non-linear. In some embodiments, the gate isolation structures 260 may be in contact with the gate spacers 221. In some embodiments, end portions of the gate isolation structures 260 have curved or non-linear profiles in a top view, as illustrated in FIG. 18C.

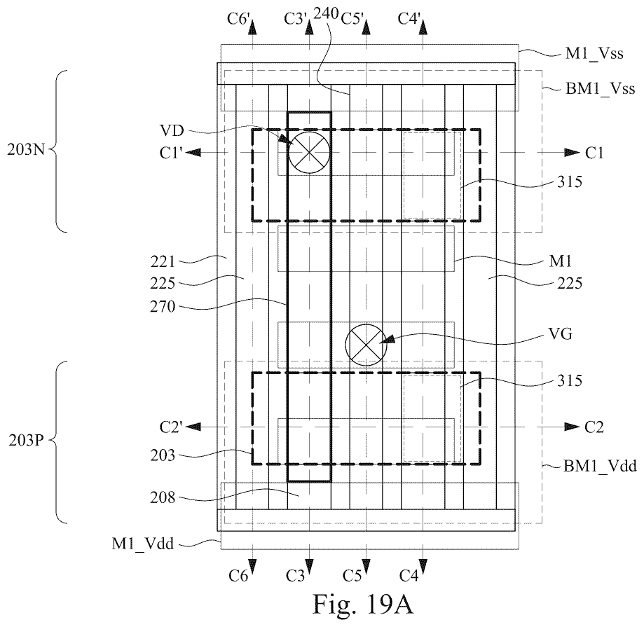

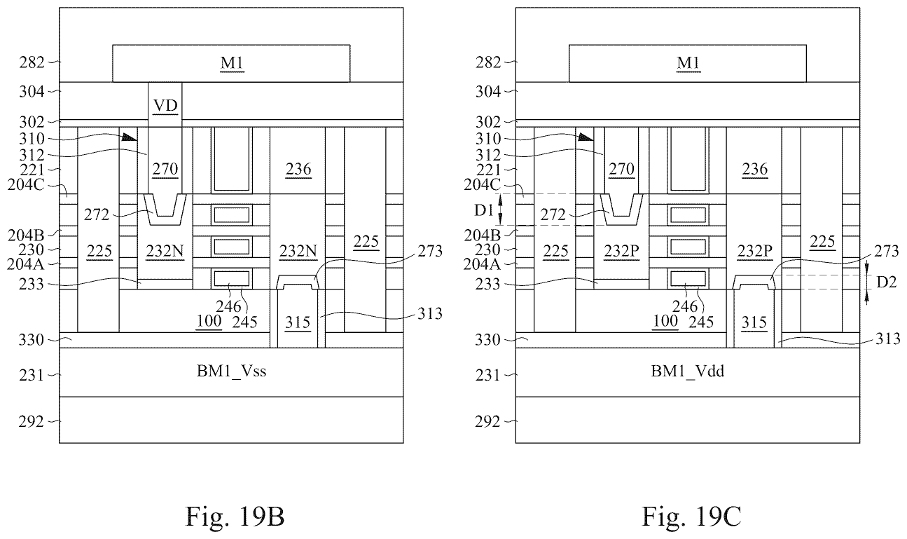

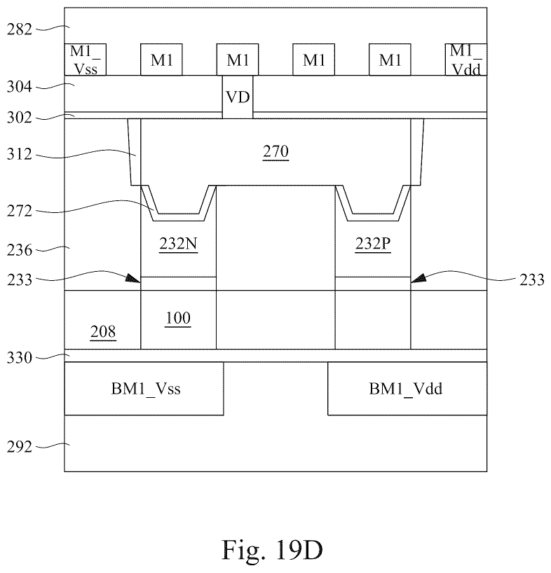

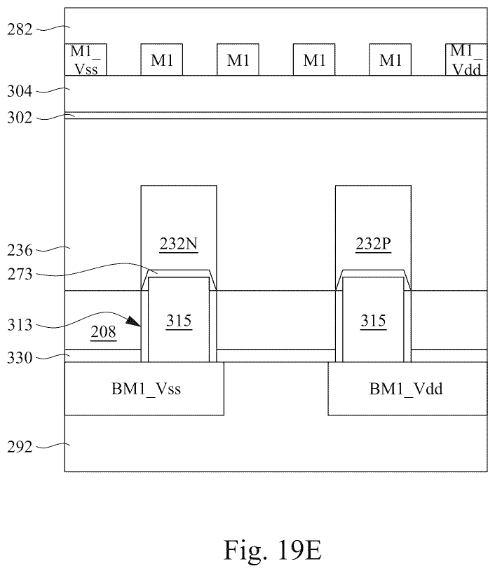

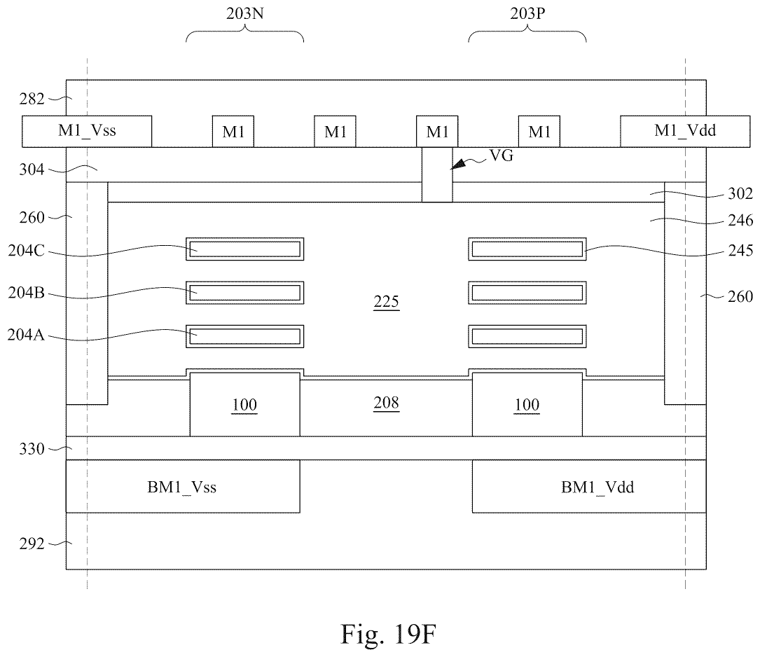

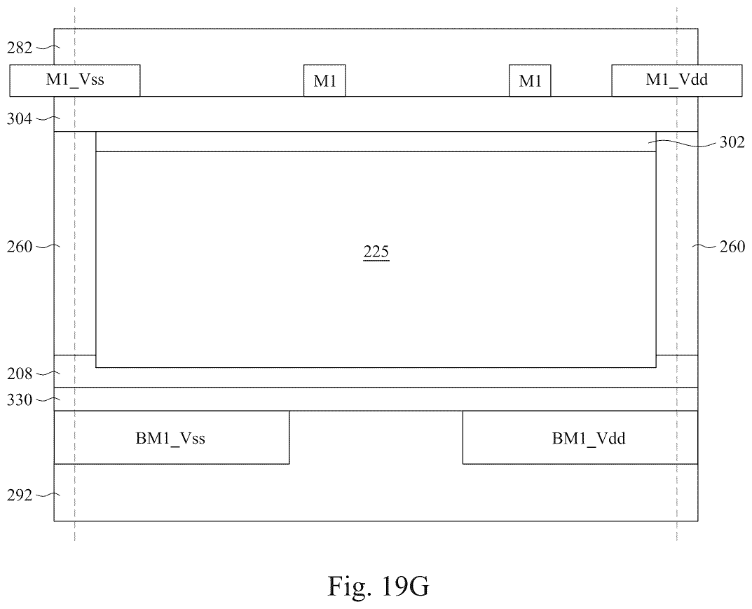

As illustrated in FIGS. 18A through 18C, after the dielectric-based gate 225 and the gate isolation structures 260 are formed, the nanostructures 203 and the gate structures 240 are cut and a cell region can be defined. Reference is made to FIGS. 19A through 19G to illustrate formation of a semiconductor structure with source/drain contacts, conductive vias and metal lines on the defined cell region of a semiconductor structure. FIGS. 19A through 19G illustrate the source/drain contacts, the conductive vias over the source/drain contacts and the gate structures, and the conductive line electrically coupled to the source/drain contacts and the gate structures through the conductive vias, in accordance with some embodiments. In one or more embodiments of the present disclosure, FIGS. 19A through 19G further illustrate formation of the backside source/drain contacts.

FIG. 19A illustrates a schematic top view of a semiconductor structure, in accordance with some embodiments. FIG. 19B illustrates a cross-sectional view along a cross-section C1-C1′ of FIG. 19A. FIG. 19C illustrates a cross-sectional view along a cross-section C2-C2′ of FIG. 19A. FIG. 19D illustrates a cross-sectional view along a cross-section C3-C3′ of FIG. 19A. FIG. 19E illustrates a cross-sectional view along a cross-section C4-C4′ of FIG. 19A. FIG. 19F illustrates a cross-sectional view along a cross-section C5-C5′ of FIG. 19A. FIG. 19G illustrates a cross-sectional view along a cross-section C6-C6′ of FIG. 19A.

In one or more embodiments, the semiconductor structure as illustrated in FIGS. 19A through 19G may include active regions 203N and 203P with different conductive types. In some embodiments, the region 203N includes a p-type well region in the substrate 100, and the source/drain regions 232 on the p-type well region in the region 203N have n-type dopant. In some embodiments, the region 203P includes an n-type well region in the substrate, and the source/drain regions 232 on the n-type well region in the region 203P have p-type dopant. A plurality of n-type source/drain regions 232N of the source/drain region 232 are formed in the active region 203N. A plurality of p-type source/drain regions 232P of the source/drain region 232 are formed in the active region 203P. In some embodiments, as illustrated in FIGS. 19A through 19G, the semiconductor structure has bottom dielectric layers 233 under the source/drain regions 232 (see FIG. 12C). In some embodiments, one of the dielectric layers 233 in the NFET region 203N is thicker than one of the dielectric layers 233 in the PFET region 203P. In some embodiments, a vertical thickness difference between one of the dielectric layers 233 in the NFET region 203N and one of the dielectric layers 233 in the PFET region 203P ranges from about 0.5 nm to about 5 nm.

As illustrated in FIGS. 19B through 19G, the dielectric layers 236 including the CESL 234 and the ILD layer 235 are etched to form contact openings 310. The contact openings 310 are formed by acceptable photolithography and etching technique and extend into the source/drain regions 232 including the source/drain regions 232N and 232P. Barrier interface layers 312 are deposited in the openings. In some embodiments, the barrier interface layers 312 include dielectric material such as silicon nitride for avoiding current leakage. In some embodiments, the barrier interface layers 312 may include SiON, SiCN, SiCON, SiCO, high-k dielectric such as HfO, AlO, or composition of multiple layers. The barrier interface layers 312 are then etched through to expose the source/drain regions 232. In one or more embodiments, the openings 310 are deepened after etching through the barrier interface layers 312.

A metal silicidation process is performed on the source/drain regions 232 to form silicide regions 272. The silicide regions 272 have curved profiles in the cross-sectional view of FIGS. 19B and 19C. The metal silicidation process is to make a reaction between metal and silicon (or polycrystalline silicon). In some embodiments, a metal layer is formed on the source/drain region 232. Subsequently, regarding the metal silicidation process, a first rapid thermal annealing (RTA) process may be performed in, for example, Ar, He, N₂ or other inert atmosphere at a first temperature, such as lower than 200~300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400~500° C., thereby forming silicide regions 272 with low resistance. The silicide regions 272 are referred to as metal silicide layers. In some embodiments, the silicide regions 272 may include titanium silicide (TiSi), TiSi₂, nickel silicide (NiSi), PtSi, MoSi, MOSi₂, cobalt silicide (CoSi), CoSi₂, Ni—Pt, or combinations thereof.

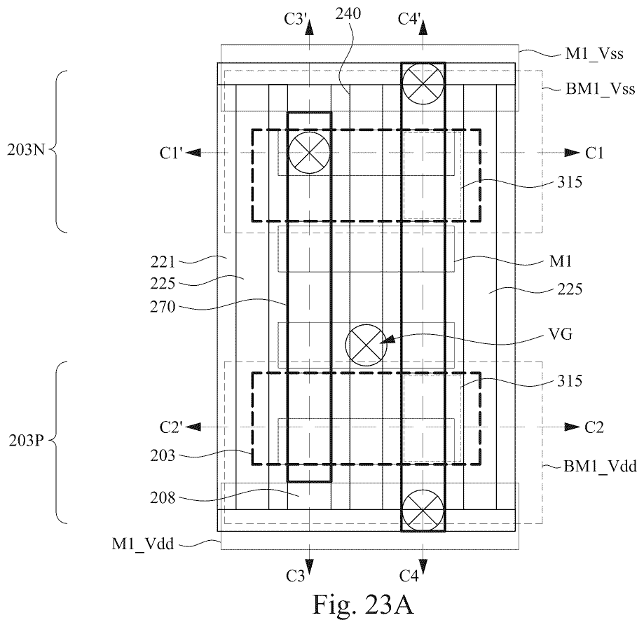

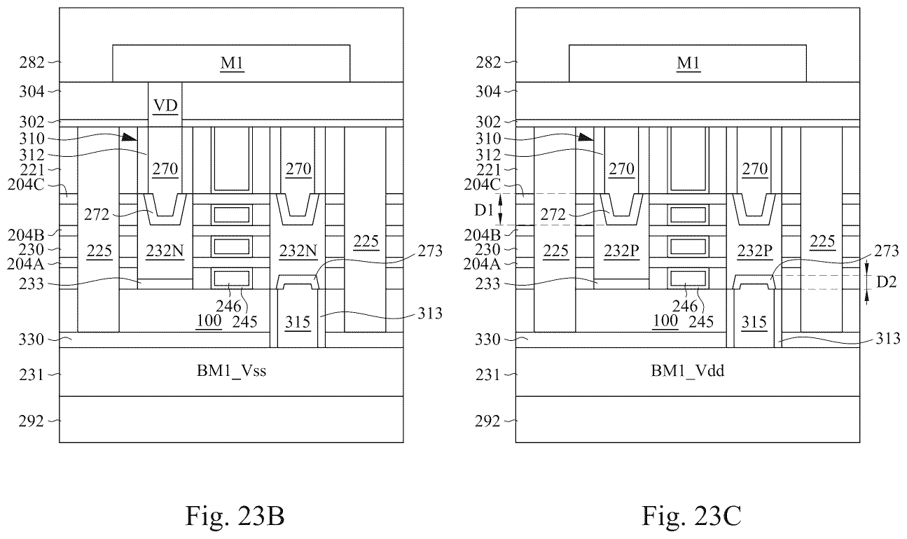

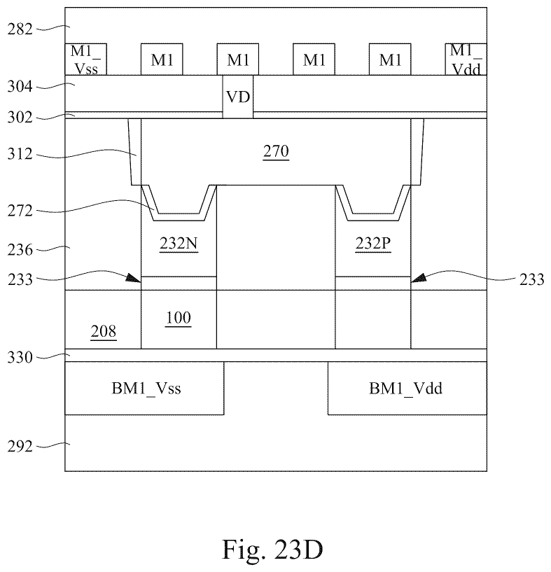

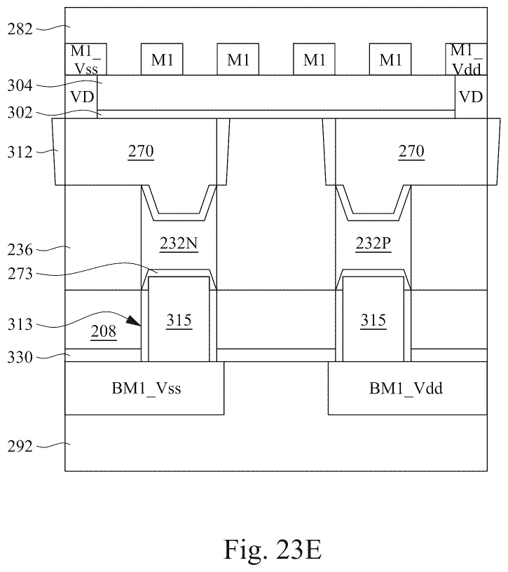

Source/drain contacts 270 (also called metal on diffusion (MD)) are subsequently formed in the dielectric layer 236. Formation of the source/drain contacts 270 includes, by way of example and not limitation, performing one or more etching processes to form contact openings 310 extending though the dielectric layer 236 to expose the source/drain epitaxy regions 232, depositing one or more metal materials (e.g., W, Ru, Co, Cu, Ti, TiN, Ta, TaN, Mo, Ni, the like or combinations thereof) overfilling the contact openings 310, and then performing a CMP process to remove excessive metal materials outside the contact openings 310. As illustrated in FIGS. 23A and 23B, the source/drain contacts 270 have inverted trapezoidal cross-sections into the source/drain regions 232P and 232N. In some embodiments, a lateral distance from the source/drain contact 270 to the gate spacer 221 increases from top of the source/drain contact 270 to bottom of the source/drain contact 270. The source/drain contacts 270 and the silicide regions 272 are collectively referred to as contact structures/features electrically coupled to the source/drain regions 232P and 232N.

A contact etch stop layer (CESL) 302 is then formed over the dielectric layer 236, the source/drain contacts 270 and the gate structures 240. The CESL 302 may be formed of a dielectric material, such as silicon nitride, silicon oxide, silicon oxynitride, or the like. The CESL 302 may be formed by any suitable method, such as CVD, ALD, or the like. An inter-layer dielectric (ILD) layer 304 can be deposited over the CESL 302. The ILD layer 304 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. The CESL 302 may have a high etching selectivity from the etching of the ILD layer 304. In some embodiments, a thickness of the CESL 302 is less than a thickness of the ILD layer 304.

Subsequently, an interconnect structure including vias VD, VG and metal lines M1, M1_Vss and M1_Vdd are formed. As illustrated in FIGS. 19A through 19G, vias VG are formed within the CESL 302 and the ILD layer 304 to electrically connect to the gate structure 240. Vias VD can be formed within the CESL 302 and the ILD layer 304 and electrically coupled to the source/drain contacts 270. Also included in the interconnect structure is an inter-metal dielectric (IMD) layer 282 formed over the ILD layer 304. In some embodiments, a contact etch stop layer is formed between the IMD layer 282 and the ILD layer 304. The IMD layer 282 may provide electrical insulation as well as structural support for the various features of the interconnect structure. In some embodiments, the IMD layer 282 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the IMD layer 282 may be made of an oxide, nitride, the like, or combinations thereof. The gate dielectrics 244 of the gate structures 240 have higher k-value than that of at least one of dielectric layers the gate spacers 221, the ILD layer 304 and the IMD layer 282. The metal lines M1 between the gate isolation structures 260 from the schematic top view of FIG. 19A are formed in the IMD layer 282 and electrically coupled to the source/drain regions 232N and 232P through the source/drain contact vias VD. The metal line M1_Vss on one of the gate isolation structures 260 from the schematic top view of FIG. 19A is interchangeably referred to as a Vss line that is provided with an electrical ground Vss. The metal line M1_Vdd on one of the gate isolation structures 260 from the schematic top view of FIG. 19A is interchangeably referred to as a Vdd line that is provided with a power supply voltage Vdd. In FIGS. 19B through 19G, the metal line M1_Vss and M1_Vdd are formed in the IMD layer 282 and electrically coupled to the source/drain regions 232N and 232P through the source/drain contact vias VD.

In one or more embodiments of the present disclosure, back-side source/drain contacts 315 are formed under the source/drain contacts 270. In some embodiments, a polish process is performed to a backside of the substrate 100, followed by forming an ILD layer 330 over the bottom of the source/drain region 232 and the remaining substrate 100. The backside source/drain contacts are then formed within the ILD layer 330 and extend into the source/drain region 232. Barrier interface layers 313 are formed on the sidewalls of the ILD layer 330. In some embodiments, the barrier interface layers 312 may include SiN, SiON, SiCN, SiCON, SiCO, high-k dielectric such as HfO, AlO, or composition of multiple layers. The backside source/drain contacts 315 may include metal-filled material similar to the material of the source/drain contact 270. As illustrated in FIGS. 19B through 19G, silicide regions 273 is formed between the source/drain region 232 and a top surface of the backside source/drain contacts 315. In some embodiments, the source/drain contacts 315 and the silicide regions 273 are collectively referred to as backside contact structures/features electrically coupled to the source/drain regions 232P and 232N. An IMD layer 292 is formed over the ILD layer 330 following formation of the backside source/drain contacts 315. The metal lines BM1_Vss and BM1_Vdd are formed in the IMD layer 292 and connected in the overlapping backside source/drain contacts 315. The metal line BM1_Vss under one of the gate isolation structures 260 from the schematic top view of FIG. 19A is interchangeably referred to as a Vss line that is provided with an electrical ground Vss. The metal line BM1_Vdd under one of the gate isolation structures 260 from the schematic top view of FIG. 19A is interchangeably referred to as a Vdd line that is provided with a power supply voltage Vdd. In FIGS. 19B through 19G, the metal lines BM1_Vss and BM1_Vdd are formed in the IMD layer 292 and electrically coupled to the source/drain regions 232N and 232P.

In some embodiments, acceptable materials of metal lines M1, M1_Vss, M1_Vdd, BM1, BM1_Vss and BM1_Vdd include Ti, TiN, TaN, Pt, Mo (Molybdenum), W (tungsten) layer, Co (Cobalt) layer, Ru (Ruthenium), W, Ir (Iridium), Rh (rhodium), Cu, or combinations thereof.

As illustrated in FIG. 19F, in some embodiments, the gate isolation structures 260 extend into the STI regions 208. In some embodiments, an extension depth of one of gate isolation structures 260 into the STI regions 208 from a top surface of the STI regions 208 to the bottom of the one of gate isolation structures 260 ranges from about 5 nm to about 60 nm.

As illustrated in FIGS. 19B and 19C, in the PFET region 203P, the front-side source/drain contact 270 and the silicide region 272 extend an extension depth D1 from a top surface of the source/drain region 232P to a bottom of the silicide region 272, and the backside source/drain contact 315 and the silicide region 273 extend an extension depth D2 into another source/drain region 232P from a bottom surface of the source/drain regions 232P to the top of the silicide region 273. In some embodiments, the extension depth D1 is an extension depth of the silicide region 272. In some embodiments, the bottom of the silicide region 272 reaches a depth of the middle-sheet portion (e.g., the nanostructure 204B). In some embodiments, the extension depth D2 is an extension depth of the silicide region 273. In one or more embodiments of the present disclosure, in order to avoid damage to the earlier formed source/drain contacts 270, the extension depth D2 of the backside source/drain contact 315 is less than the extension depth D1 of the front-side source/drain contact 270. In some embodiments, a difference between the extension depths D1 and D2 ranges from about 3 nm to about 20 nm.

In some embodiments, as illustrated in FIGS. 19A and 19F, the source/drain contact 270 and the gate structure 240 extends across the NFET region 203N and the PFET region 203P. In NFET region 203N, the nanostructures 204A-204C, the source/drain regions 232N and the gate structure 240 form a n-type transistor. In PFET region 203P, the nanostructures 204A-204C, the source/drain regions 232P and the gate structure 240 form a p-type transistor. The source/drain contact 270 can be referred to as a common source/drain contact connecting the source/drain region 232N of the n-type transistor in the NFET region 203N to the source/drain region 232P of the p-type transistor in the PFET region 203P, the gate structure 240 can be referred to as a common gate structure of the n-type transistor in the NFET region 203N and the p-type transistor in the PFET region 203P, and the n-type transistor in the NFET region 203N and the p-type transistor in the PFET region 203P thus form a complementary metal-oxide-semiconductor (CMOS) structure.

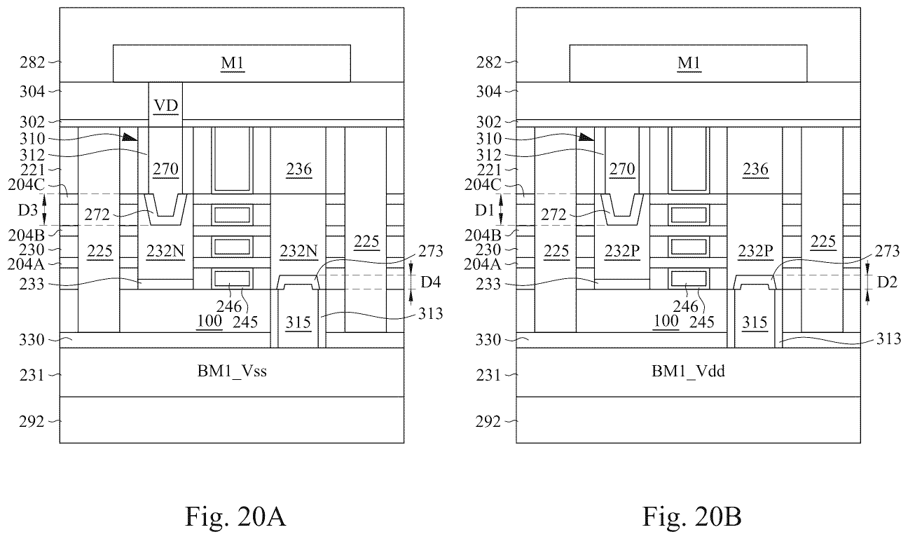

Reference is made to FIGS. 20A and 20B. FIGS. 20A and 20B illustrate cross-sectional views of a semiconductor structure, in accordance with some embodiments. FIG. 20A corresponds to the cross-section C1-C1′ of FIG. 19A. FIG. 20B corresponds to the cross-section C2-C2′ of FIG. 19A. As illustrated in FIGS. 20A and 20B, the semiconductor structure in FIGS. 20A and 20B is substantially the same as the semiconductor structure in FIG. 19B through 19C, except that the extension depth D1 of the front-side source/drain contact 270 in the PFET region 203P is reduced. As illustrated in FIGS. 20A and 20B, in the NFET region 203N, the front-side source/drain contact 270 and the silicide region 272 extend an extension depth D3 from a top surface of the source/drain region 232N to a bottom of the silicide region 272, the backside source/drain contact 315 and the silicide region 273 extend an extension depth D4 from a bottom surface of the source/drain region 232N to a top of the silicide region 273. In some embodiments, the extension depth D3 is an extension depth of the silicide region 272 in the source/drain region 232N. In some embodiments, the extension depth D4 is an extension depth of the silicide region 273 in the source/drain region 232N. The extension depth D4 is less than the extension depth D3. In some embodiments, a difference between the extension depths D3 and D4 ranges from about 3 nm to about 20 nm. In some embodiments, the extension depth D1 of the front-side source/drain contact 270 in the PFET region 203P is less than the extension depth D3 of the front-side source/drain contact 270 in the NFET region 203N. In some embodiments, a difference between the extension depths D1 and D3 ranges from about 2 nm to about 15 nm.

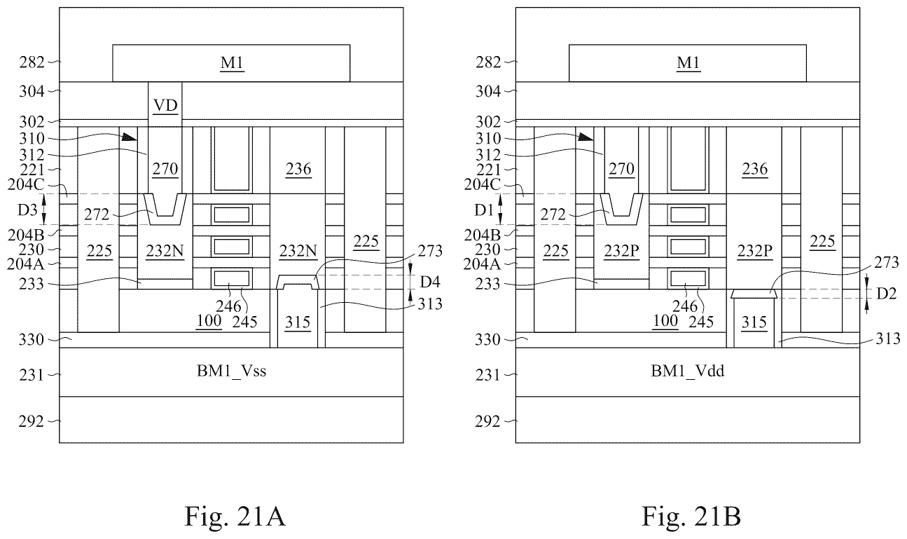

Reference is made to FIGS. 21A and 21B. FIGS. 21A and 21B illustrate cross-sectional views of a semiconductor structure, in accordance with some embodiments. FIG. 21A corresponds to the cross-section C1-C1′ of FIG. 19A. FIG. 21B corresponds to the cross-section C2-C2′ of FIG. 19A. As illustrated in FIGS. 21A and 21B, the semiconductor structure in FIGS. 21A and 21B is substantially the same as the semiconductor structure in FIG. 20B through 20C, except that the extension depth D2 of the backside source/drain contact 315 in the PFET region 203P is reduced to near zero. In other words, the backside source/drain contact 315 in the PFET region 203P extends into the source/drain region 232P a little or just touches the bottom surface of the source/drain region 232P. In some embodiments, in the semiconductor structure as illustrated in FIGS. 21A and 21B, the bottom dielectric layers 231 are selectively formed and no bottom dielectric layer 231 is between the backside source/drain contact 315 and the source/drain region 232P in the PFET region 203P. In FIGS. 21A and 21B, the extension depth D2 of the backside source/drain contact 315 in the PFET region 203P is less than the extension depth D4 of the backside source/drain contact 315 in the NFET region 203N. In some embodiments, a difference between the extension depths D2 and D4 ranges from about 2 nm to about 15 nm.

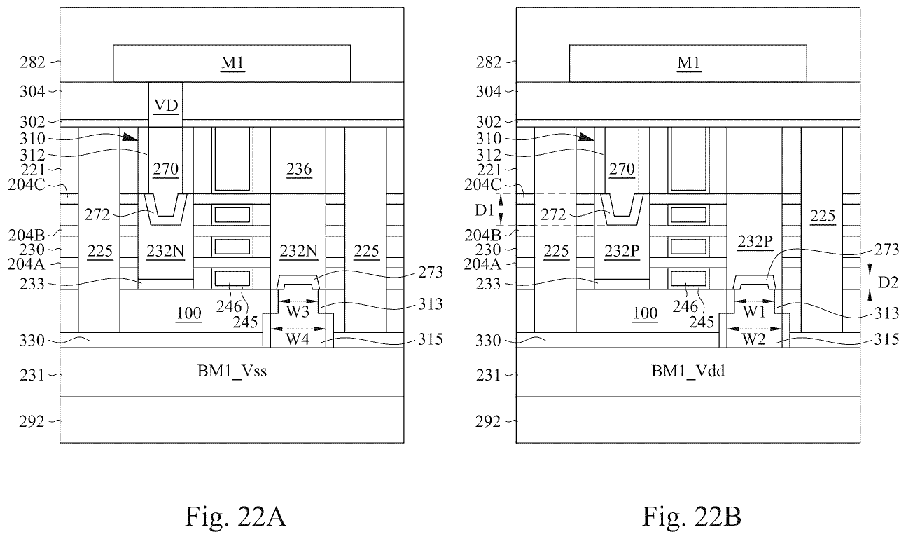

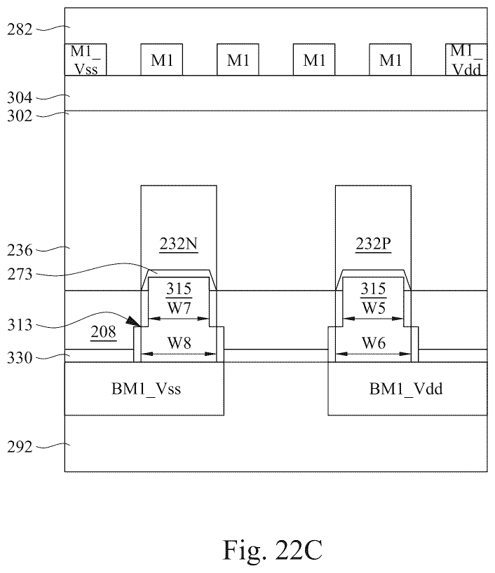

Reference is made to FIGS. 22A and 22B. FIGS. 22A and 22B illustrate cross-sectional views of a semiconductor structure, in accordance with some embodiments. FIG. 22A corresponds to the cross-section C1-C1′ of FIG. 19A. FIG. 22B corresponds to the cross-section C2-C2′ of FIG. 19A. As illustrated in FIGS. 22A and 22B, the semiconductor structure in FIGS. 22A and 22B is substantially the same as the semiconductor structure in FIG. 19B through 19C, except that the backside source/drain contacts 315 in the NFET region 203N and the PFET region 203P have different widths at different heights. In some embodiments, formation of the backside source/drain contacts 315 may include two-step etching. For example, formation of the backside source/drain contacts 315 includes forming a first trench in the ILD layer 330 and into the substrate 100 and forming a second trench from a bottom of the first trench to the source/drain region 232, wherein the first trench is wider than the second trench. In FIGS. 22A and 22B, the backside source/drain contact 315 in the PFET region 203P has a first portion connected to the silicide region 273 with a width W1 and a second portion under the first portion with a width W2, and the width W1 is less than the width W2. In some embodiments, the width W1 ranges from about 7 nm to about 20 nm. In some embodiments, the width W2 ranges from about 12 nm to about 40 nm. In some embodiments, a ratio of the width W2 to the width W1 ranges from about 1.1 to about 3. The backside source/drain contact 315 in the NFET region 203N has a first portion connected to the silicide region 273 with a width W3 and a second portion under the first portion with a width W4, and the width W3 is less than the width W4. In some embodiments, a ratio of the width W4 to the width W3 ranges from about 1.1 to about 3.

FIG. 22C illustrates a cross-sectional view of the semiconductor structure as illustrated in FIGS. 22A and 22B, in accordance with some embodiments. FIG. 22C corresponds to the cross-section C4-C4′ of FIG. 19A. As illustrated in FIG. 22C, the backside source/drain contacts 315 have different widths at different heights. In the cross-sectional view as illustrated in FIG. 22C, the backside source/drain contact 315 under the source/drain region 232P in the PFET region 203P has the first portion with the width W5 and the second portion under the first portion with a width W6, and the width W5 is less than the width W6. In some embodiments, a ratio of the width W6 to the width W5 ranges from about 1.1 to about 3. The backside source/drain contact 315 under the source/drain region 232N in the NFET region 203N has the first portion with the width W7 and the second portion under the first portion with a width W8, and the width W7 is less than the width W8. In some embodiments, a ratio of the width W8 to the width W7 ranges from about 1.1 to about 3.

Reference is made to FIGS. 23A through 23E to illustrate a semiconductor structure in accordance with some embodiments. FIG. 23A illustrates a schematic top view of a semiconductor structure, in accordance with some embodiments. FIG. 23B illustrates a cross-sectional view along a cross-section C1-C1′ of FIG. 23A. FIG. 23C illustrates a cross-sectional view along a cross-section C2-C2′ of FIG. 23A. FIG. 23D illustrates a cross-sectional view along a cross-section C3-C3′ of FIG. 23A. FIG. 23E illustrates a cross-sectional view along a cross-section C4-C4′ of FIG. 23A.

As illustrated in FIGS. 23A through 23E, the semiconductor structure in FIGS. 23A through 23E is substantially the same as the semiconductor structure in FIG. 19A through 19G, except that the semiconductor structure in FIGS. 23A through 23E further includes additional front-side source/drain contacts 270 on the source/drain regions 232P and 232N above the backside source/drain contacts 315 and vias VD overlapping the additional front-side source/drain contacts 270. The front-side source/drain contact 270 on the source/drain region 232N above the backside source/drain contacts 315 is electrically coupled to the metal line M1_Vss through the overlapping via VD. The front-side source/drain contact 270 on the source/drain region 232P above the backside source/drain contacts 315 is electrically coupled to the metal line M1_Vdd through the overlapping via VD. The source/drain contacts 270 connected to the Vss line and the Vdd line from the front-side and the backside of the substrate 100 form serial connection to the Vss line and the Vdd line and thus reduce the contact resistance.

As illustrated in FIGS. 23B and 23C, in the PFET region 203P, the front-side source/drain contact 270 and the silicide region 272 extend an extension depth D1 from a top surface of the source/drain region 232P to a bottom of the silicide region 272, and the backside source/drain contact 315 and the silicide region 273 extend an extension depth D2 into another source/drain region 232P from a bottom surface of the source/drain regions 232P to the top of the silicide region 273. In some embodiments, the extension depth D1 is an extension depth of the silicide region 272. In some embodiments, the extension depth D2 is an extension depth of the silicide region 273. In one or more embodiments of the present disclosure, in order to avoid damage to the earlier formed source/drain contacts 270, the extension depth D2 of the backside source/drain contact 315 is less than the extension depth D1 of the front-side source/drain contact 270. In some embodiments, a difference between the extension depths D1 and D2 ranges from about 3 nm to about 20 nm.

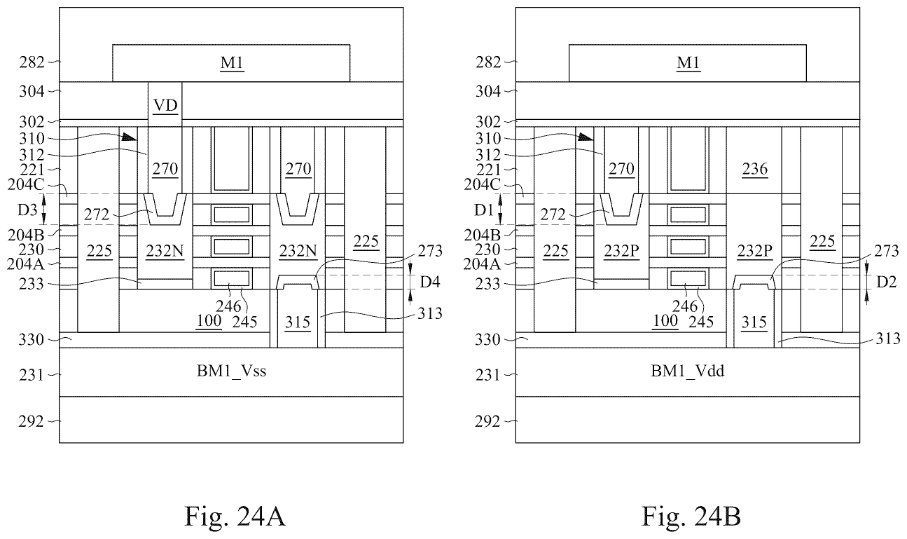

Reference is made to FIGS. 24A and 24B. FIGS. 24A and 24B illustrate cross-sectional views of a semiconductor structure, in accordance with some embodiments. FIG. 24A corresponds to the cross-section C1-C1′ of FIG. 23A. FIG. 24B corresponds to the cross-section C2-C2′ of FIG. 23A. As illustrated in FIGS. 24A and 24B, the semiconductor structure in FIGS. 24A and 24B is substantially the same as the semiconductor structure in FIGS. 23B and 23C, except that the extension depth D1 of the front-side source/drain contact 270 in the PFET region 203P is reduced. As illustrated in FIGS. 24A and 24B, in the NFET region 203N, the front-side source/drain contact 270 and the silicide region 272 extend an extension depth D3 from a top surface of the source/drain region 232N to a bottom of the silicide region 272, the backside source/drain contact 315 and the silicide region 273 extend an extension depth D4 from a bottom surface of the source/drain region 232N to a top of the silicide region 273. In some embodiments, the extension depth D3 is an extension depth of the silicide region 272 in the source/drain region 232N. In some embodiments, the extension depth D4 is an extension depth of the silicide region 273 in the source/drain region 232N. The extension depth D4 is less than the extension depth D3. In some embodiments, a difference between the extension depths D3 and D4 ranges from about 3 nm to about 20 nm. In some embodiments, the extension depth D1 of the front-side source/drain contact 270 in the PFET region 203P is less than the extension depth D3 of the front-side source/drain contact 270 in the NFET region 203N. In some embodiments, a difference between the extension depths D1 and D3 ranges from about 2 nm to about 15 nm.

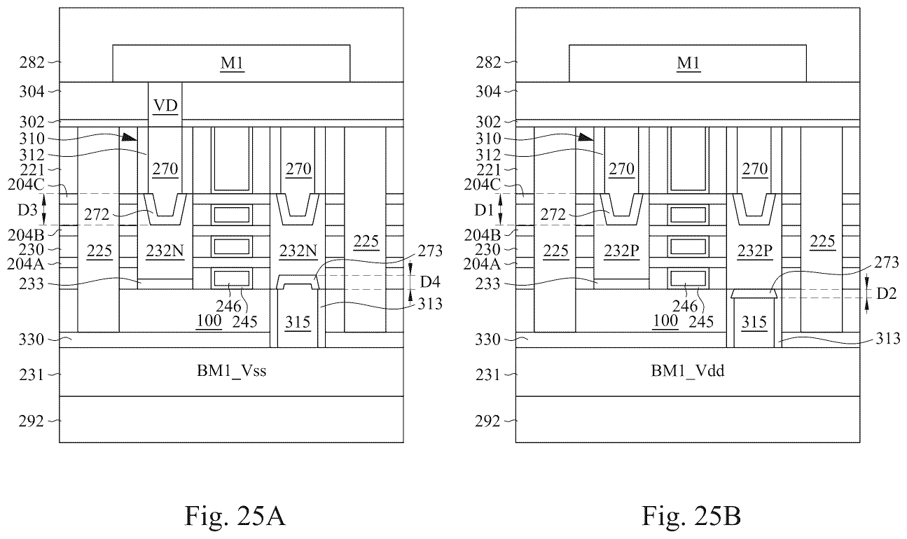

Reference is made to FIGS. 25A and 25B. FIGS. 25A and 25B illustrate cross-sectional views of a semiconductor structure, in accordance with some embodiments. FIG. 25A corresponds to the cross-section C1-C1′ of FIG. 23A. FIG. 25B corresponds to the cross-section C2-C2′ of FIG. 23A. As illustrated in FIGS. 25A and 25B, the semiconductor structure in FIGS. 25A and 25B is substantially the same as the semiconductor structure in FIGS. 24A and 24B, except that the extension depth D2 of the backside source/drain contact 315 in the PFET region 203P is reduced to near zero. In other words, the backside source/drain contact 315 in the PFET region 203P extends into the source/drain region 232P a little or just touches the bottom surface of the source/drain region 232P. In some embodiments, in the semiconductor structure as illustrated in FIGS. 25A and 25B, the bottom dielectric layers 231 are selectively formed and no bottom dielectric layer 231 is between the backside source/drain contact 315 and the source/drain region 232P in the PFET region 203P. In FIGS. 25A and 25B, the extension depth D2 of the backside source/drain contact 315 in the PFET region 203P is less than the extension depth D4 of the backside source/drain contact 315 in the NFET region 203N. In some embodiments, a difference between the extension depths D2 and D4 ranges from about 2 nm to about 15 nm.

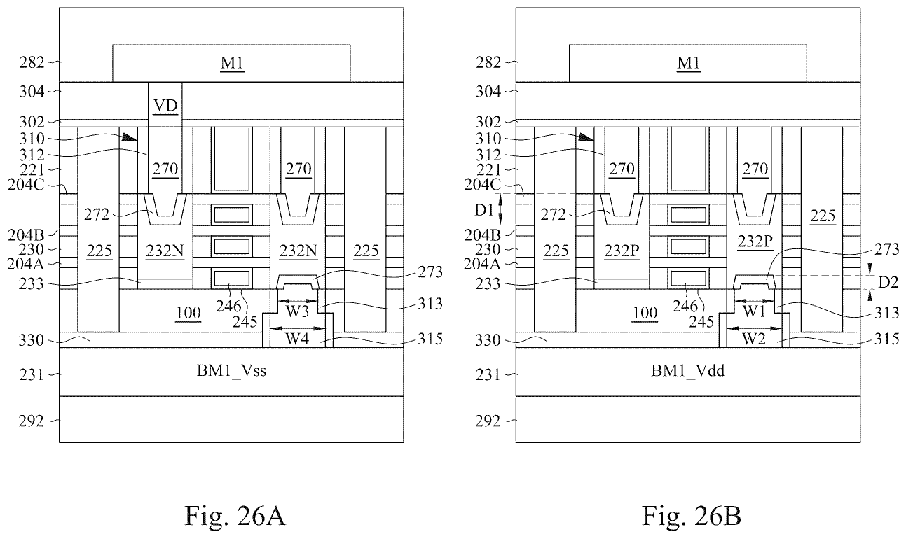

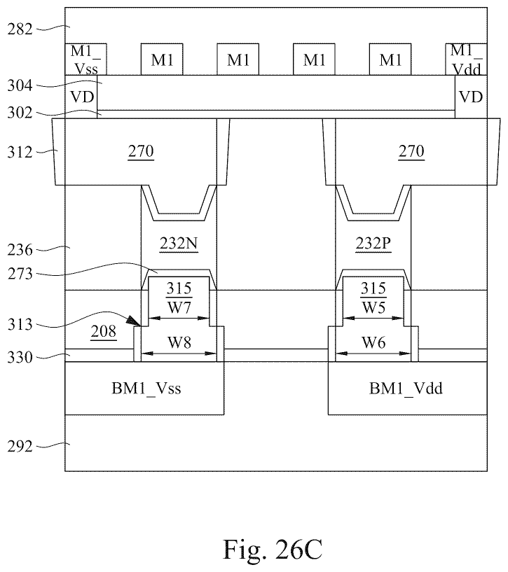

Reference is made to FIGS. 26A and 26B. FIGS. 26A and 26B illustrate cross-sectional views of a semiconductor structure, in accordance with some embodiments. FIG. 26A corresponds to the cross-section C1-C1′ of FIG. 23A. FIG. 26B corresponds to the cross-section C2-C2′ of FIG. 23A. As illustrated in FIGS. 26A and 26B, the semiconductor structure in FIGS. 26A and 26B is substantially the same as the semiconductor structure in FIGS. 23B and 23C, except that the backside source/drain contacts 315 in the NFET region 203N and the PFET region 203P have different widths at different heights. In some embodiments, formation of the backside source/drain contacts 315 may include two-step etching. For example, formation of the backside source/drain contacts 315 includes forming a first trench in the ILD layer 330 and into the substrate 100 and forming a second trench from a bottom of the first trench to the source/drain region 232, wherein the first trench is wider than the second trench. In FIGS. 26A and 26B, the backside source/drain contact 315 in the PFET region 203P has a first portion connected to the silicide region 273 with a width W1 and a second portion under the first portion with a width W2, and the width W1 is less than the width W2. In some embodiments, a ratio of the width W2 to the width W1 ranges from about 1.1 to about 3. The backside source/drain contact 315 in the NFET region 203N has a first portion connected to the silicide region 273 with a width W3 and a second portion under the first portion with a width W4, and the width W3 is less than the width W4. In some embodiments, a ratio of the width W4 to the width W3 ranges from about 1.1 to about 3.

FIG. 26C illustrates a cross-sectional view of the semiconductor structure as illustrated in FIGS. 26A and 26B, in accordance with some embodiments. FIG. 26C corresponds to the cross-section C4-C4′ of FIG. 23A. As illustrated in FIG. 26C, the backside source/drain contacts 315 have different widths at different heights. In the cross-sectional view as illustrated in FIG. 26C, the backside source/drain contact 315 under the source/drain region 232P in the PFET region 203P has the first portion with the width W5 and the second portion under the first portion with a width W6, and the width W5 is less than the width W6. In some embodiments, a ratio of the width W6 to the width W5 ranges from about 1.1 to about 3. The backside source/drain contact 315 under the source/drain region 232N in the NFET region 203N has the first portion with the width W7 and the second portion under the first portion with a width W8, and the width W7 is less than the width W8. In some embodiments, a ratio of the width W8 to the width W7 ranges from about 1.1 to about 3.

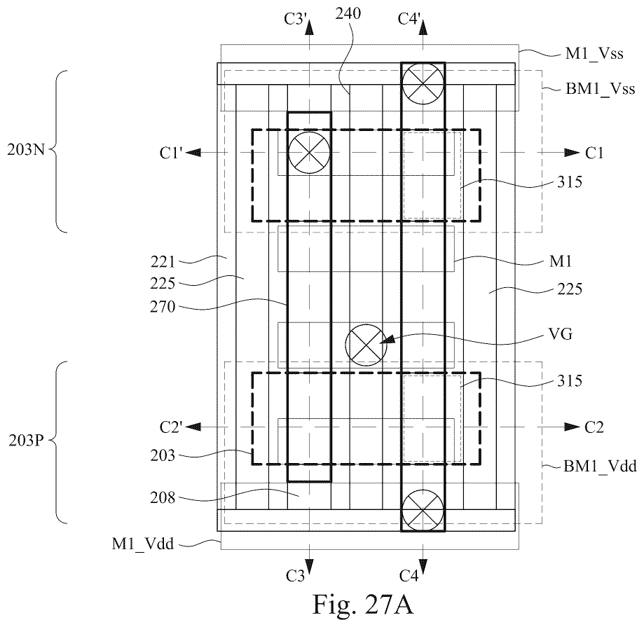

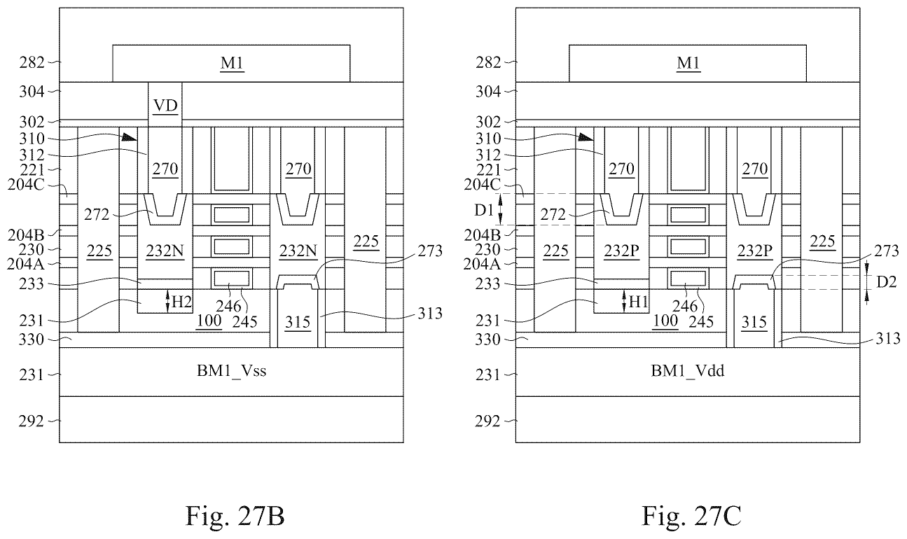

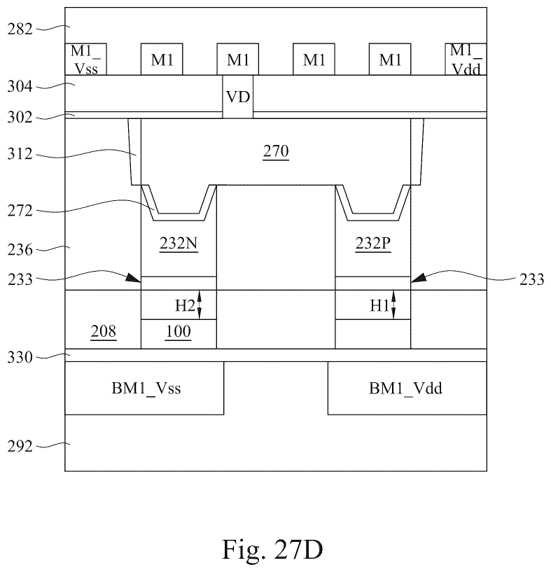

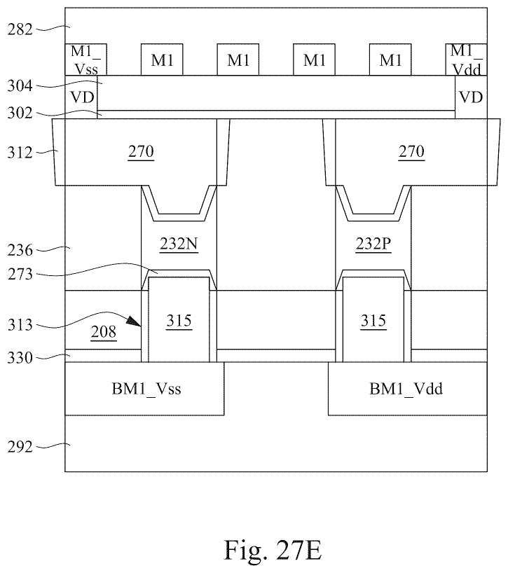

Reference is made to FIGS. 27A through 27E to illustrate a semiconductor structure in accordance with some embodiments. FIG. 27A illustrates a schematic top view of a semiconductor structure, in accordance with some embodiments. FIG. 27B illustrates a cross-sectional view along a cross-section C1-C1′ of FIG. 27A. FIG. 27C illustrates a cross-sectional view along a cross-section C2-C2′ of FIG. 27A. FIG. 27D illustrates a cross-sectional view along a cross-section C3-C3′ of FIG. 27A. FIG. 27E illustrates a cross-sectional view along a cross-section C4-C4′ of FIG. 27A.

As illustrated in FIGS. 27A through 27E, the semiconductor structure in FIGS. 27A through 27E is substantially the same as the semiconductor structure in FIG. 23A through 23E, except that the semiconductor structure in FIGS. 27A through 27E further includes un-doped semiconductor layers 231 under the bottom dielectric layers 233 (see FIG. 12D). In some embodiments, the un-doped semiconductor layers 231 have different material from the substrate 100 so that the un-doped semiconductor layers 231 and the substrate 100 can have etch/polish selectivity. The un-doped semiconductor layers 231 can thus be referred to as sacrificial layers in some etch processes. The un-doped semiconductor layer 231 in the PFET region 203P has a height H1. The un-doped semiconductor layer 231 in the NFET region 203N has a height H2. In some embodiments, the height H1 is different from the height H2. In some embodiments, the height H1 is substantially equal to the height H2.

As illustrated in FIGS. 27B and 27C, in the PFET region 203P, the front-side source/drain contact 270 and the silicide region 272 extend an extension depth D1 from a top surface of the source/drain region 232P to a bottom of the silicide region 272, and the backside source/drain contact 315 and the silicide region 273 extend an extension depth D2 into another source/drain region 232P from a bottom surface of the source/drain regions 232P to the top of the silicide region 273. In some embodiments, the extension depth D1 is an extension depth of the silicide region 272. In some embodiments, the extension depth D2 is an extension depth of the silicide region 273. In one or more embodiments of the present disclosure, in order to avoid damage to the earlier formed source/drain contacts 270, the extension depth D2 of the backside source/drain contact 315 is less than the extension depth D1 of the front-side source/drain contact 270. In some embodiments, a difference between the extension depths D1 and D2 ranges from about 3 nm to about 20 nm.

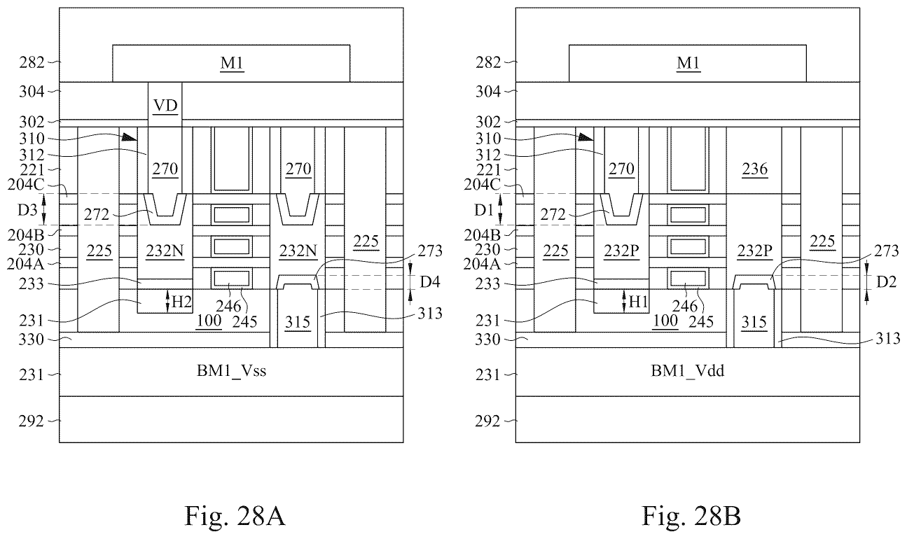

Reference is made to FIGS. 28A and 28B. FIGS. 28A and 28B illustrate cross-sectional views of a semiconductor structure, in accordance with some embodiments. FIG. 28A corresponds to the cross-section C1-C1′ of FIG. 27A. FIG. 28B corresponds to the cross-section C2-C2′ of FIG. 27A. As illustrated in FIGS. 28A and 28B, the semiconductor structure in FIGS. 28A and 28B is substantially the same as the semiconductor structure in FIGS. 27B and 27C, except that the extension depth D1 of the front-side source/drain contact 270 in the PFET region 203P is reduced. As illustrated in FIGS. 28A and 28B, in the NFET region 203N, the front-side source/drain contact 270 and the silicide region 272 extend an extension depth D3 from a top surface of the source/drain region 232N to a bottom of the silicide region 272, the backside source/drain contact 315 and the silicide region 273 extend an extension depth D4 from a bottom surface of the source/drain region 232N to a top of the silicide region 273. In some embodiments, the extension depth D3 is an extension depth of the silicide region 272 in the source/drain region 232N. In some embodiments, the extension depth D4 is an extension depth of the silicide region 273 in the source/drain region 232N. The extension depth D4 is less than the extension depth D3. In some embodiments, a difference between the extension depths D3 and D4 ranges from about 3 nm to about 20 nm. In some embodiments, the extension depth D1 of the front-side source/drain contact 270 in the PFET region 203P is less than the extension depth D3 of the front-side source/drain contact 270 in the NFET region 203N. In some embodiments, a difference between the extension depths D1 and D3 ranges from about 2 nm to about 15 nm.

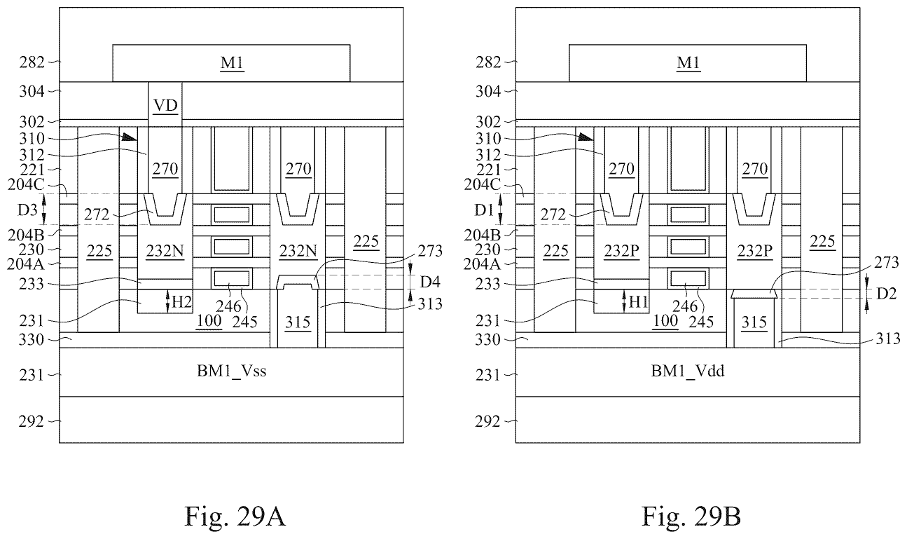

Reference is made to FIGS. 29A and 29B. FIGS. 29A and 29B illustrate cross-sectional views of a semiconductor structure, in accordance with some embodiments. FIG. 29A corresponds to the cross-section C1-C1′ of FIG. 27A. FIG. 29B corresponds to the cross-section C2-C2′ of FIG. 27A. As illustrated in FIGS. 29A and 29B, the semiconductor structure in FIGS. 29A and 29B is substantially the same as the semiconductor structure in FIGS. 28A and 28B, except that the extension depth D2 of the backside source/drain contact 315 in the PFET region 203P is reduced to near zero. In other words, the backside source/drain contact 315 in the PFET region 203P extends into the source/drain region 232P a little or just touches the bottom surface of the source/drain region 232P. In some embodiments, in the semiconductor structure as illustrated in FIGS. 29A and 29B, the bottom dielectric layers 231 are selectively formed and no bottom dielectric layer 231 is between the backside source/drain contact 315 and the source/drain region 232P in the PFET region 203P. In FIGS. 29A and 29B, the extension depth D2 of the backside source/drain contact 315 in the PFET region 203P is less than the extension depth D4 of the backside source/drain contact 315 in the NFET region 203N. In some embodiments, a difference between the extension depths D2 and D4 ranges from about 2 nm to about 15 nm.

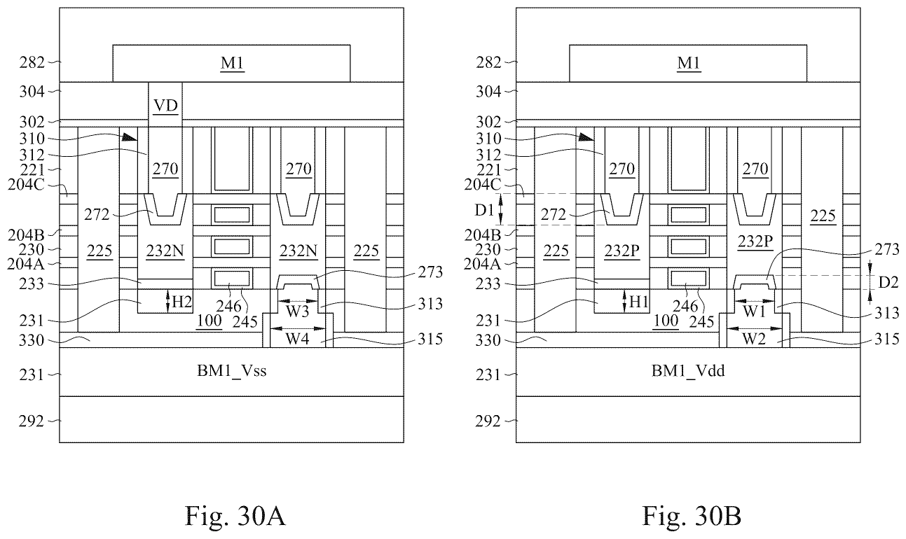

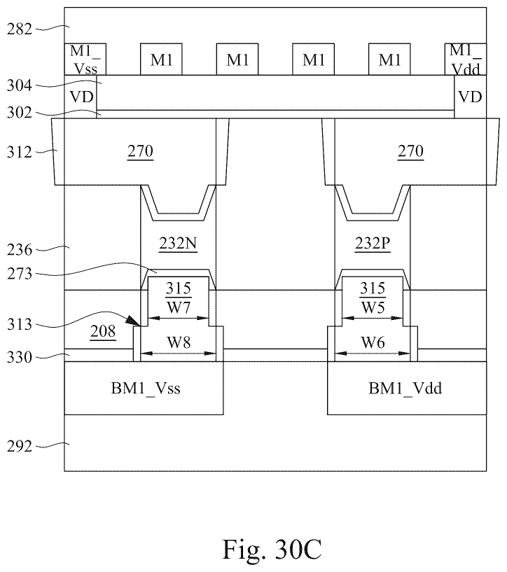

Reference is made to FIGS. 30A and 30B. FIGS. 30A and 30B illustrate cross-sectional views of a semiconductor structure, in accordance with some embodiments. FIG. 30A corresponds to the cross-section C1-C1′ of FIG. 27A. FIG. 30B corresponds to the cross-section C2-C2′ of FIG. 27A. As illustrated in FIGS. 30A and 30B, the semiconductor structure in FIGS. 30A and 30B is substantially the same as the semiconductor structure in FIGS. 27B and 27C, except that the backside source/drain contacts 315 in the NFET region 203N and the PFET region 203P have different widths at different heights. In some embodiments, formation of the backside source/drain contacts 315 may include two-step etching. For example, formation of the backside source/drain contacts 315 includes forming a first trench in the ILD layer 330 and into the substrate 100 and forming a second trench from a bottom of the first trench to the source/drain region 232, wherein the first trench is wider than the second trench. In some embodiments, the first trench with a wider width can be formed using the un-doped semiconductor layers 231 referred to as sacrificial layers. The etching of the first trench can stop at a bottom surface of the un-doped semiconductor layers 231 under the bottom dielectric layer 233. The etching of the second trench is then performed to etch the bottom dielectric layer 233 from a bottom of the first trench. In FIGS. 30A and 30B, the backside source/drain contact 315 in the PFET region 203P has a first portion connected to the silicide region 273 with a width W1 and a second portion under the first portion with a width W2, and the width W1 is less than the width W2. A top surface of the first portion of the backside source/drain contact 315 with the width W2 can be substantially level with a bottom surface of the un-doped semiconductor layer 231 in the PFET region 203P. In some embodiments, a ratio of the width W2 to the width W1 ranges from about 1.1 to about 3. The backside source/drain contact 315 in the NFET region 203N has a first portion connected to the silicide region 273 with a width W3 and a second portion under the first portion with a width W4, and the width W3 is less than the width W4. A top surface of the second portion of the backside source/drain contact 315 with the width W4 can be substantially level with a bottom surface of the un-doped semiconductor layer 231 in the NFET region 203N. In some embodiments, a ratio of the width W4 to the width W3 ranges from about 1.1 to about 3.

FIG. 30C illustrates a cross-sectional view of the semiconductor structure as illustrated in FIGS. 30A and 30B, in accordance with some embodiments. FIG. 30C corresponds to the cross-section C4-C4′ of FIG. 27A. As illustrated in FIG. 30C, the backside source/drain contacts 315 have different widths at different heights. In the cross-sectional view as illustrated in FIG. 30C, the backside source/drain contact 315 under the source/drain region 232P in the PFET region 203P has the first portion with the width W5 and the second portion under the first portion with a width W6, and the width W5 is less than the width W6. In some embodiments, a ratio of the width W6 to the width W5 ranges from about 1.1 to about 3. The backside source/drain contact 315 under the source/drain region 232N in the NFET region 203N has the first portion with the width W7 and the second portion under the first portion with a width W8, and the width W7 is less than the width W8. In some embodiments, a ratio of the width W8 to the width W7 ranges from about 1.1 to about 3.

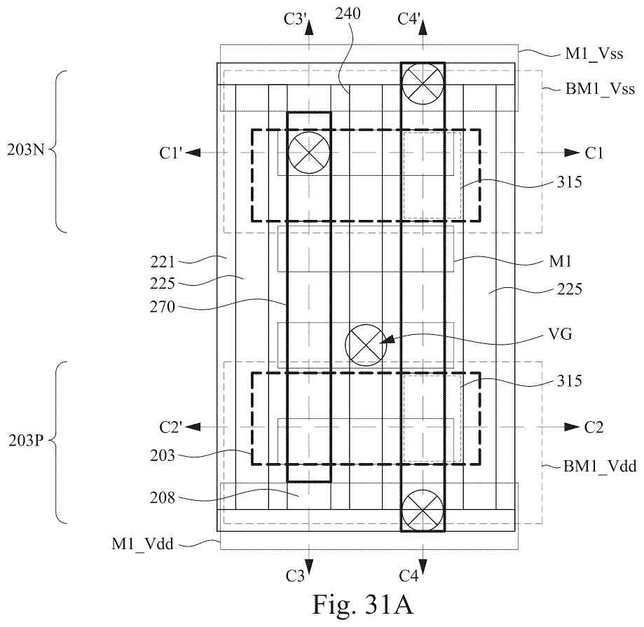

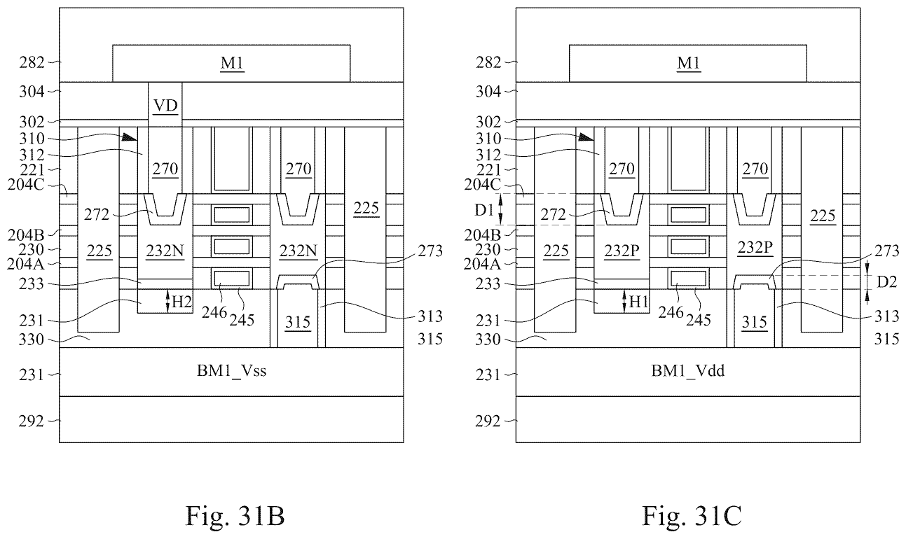

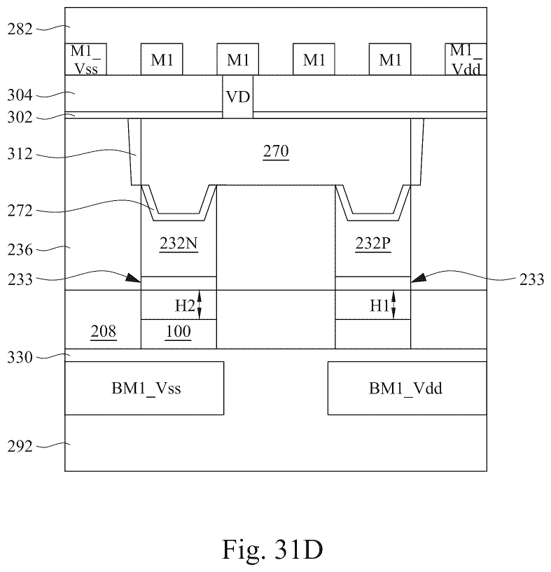

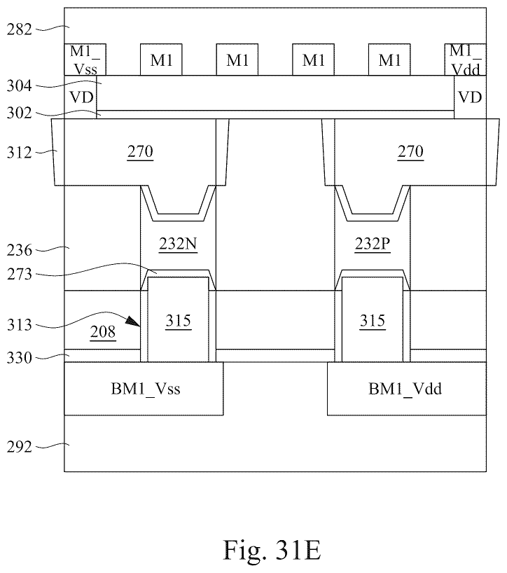

Reference is made to FIGS. 31A through 31E to illustrate a semiconductor structure in accordance with some embodiments. FIG. 31A illustrates a schematic top view of a semiconductor structure, in accordance with some embodiments. FIG. 31B illustrates a cross-sectional view along a cross-section C1-C1′ of FIG. 31A. FIG. 31C illustrates a cross-sectional view along a cross-section C2-C2′ of FIG. 31A. FIG. 31D illustrates a cross-sectional view along a cross-section C3-C3′ of FIG. 31A. FIG. 31E illustrates a cross-sectional view along a cross-section C4-C4′ of FIG. 31A.

As illustrated in FIGS. 31A through 31E, the semiconductor structure in FIGS. 31A through 31E is substantially the same as the semiconductor structure in FIG. 27A through 27E, except that most of the substrate 100 of the semiconductor structure in FIGS. 31A through 31E are polished and the ILD layer 330 is formed on the bottom most portions of the gate structures 240 and the bottommost inner spacers 230. The un-doped semiconductor layers 231 are embedded in the ILD layer 330.

As illustrated in FIGS. 31B and 31C, in the PFET region 203P, the front-side source/drain contact 270 and the silicide region 272 extend an extension depth D1 from a top surface of the source/drain region 232P to a bottom of the silicide region 272, and the backside source/drain contact 315 and the silicide region 273 extend an extension depth D2 into another source/drain region 232P from a bottom surface of the source/drain regions 232P to the top of the silicide region 273. In some embodiments, the extension depth D1 is an extension depth of the silicide region 272. In some embodiments, the extension depth D2 is an extension depth of the silicide region 273. In one or more embodiments of the present disclosure, in order to avoid damage to the earlier formed source/drain contacts 270, the extension depth D2 of the backside source/drain contact 315 is less than the extension depth D1 of the front-side source/drain contact 270. In some embodiments, a difference between the extension depths D1 and D2 ranges from about 3 nm to about 20 nm.

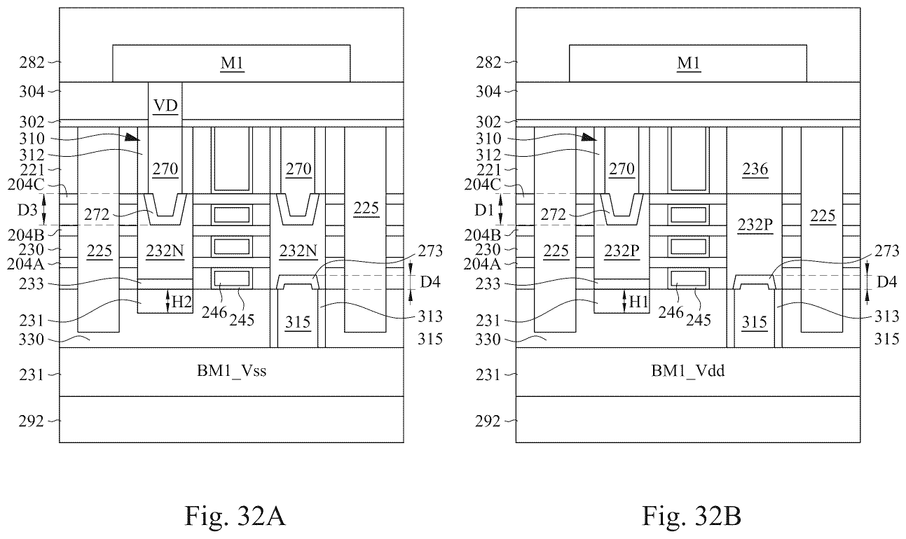

Reference is made to FIGS. 32A and 32B. FIGS. 32A and 32B illustrate cross-sectional views of a semiconductor structure, in accordance with some embodiments. FIG. 32A corresponds to the cross-section C1-C1′ of FIG. 31A. FIG. 32B corresponds to the cross-section C2-C2′ of FIG. 31A. As illustrated in FIGS. 32A and 32B, the semiconductor structure in FIGS. 32A and 32B is substantially the same as the semiconductor structure in FIGS. 31B and 31C, except that the extension depth D1 of the front-side source/drain contact 270 in the PFET region 203P is reduced. As illustrated in FIGS. 32A and 32B, in the NFET region 203N, the front-side source/drain contact 270 and the silicide region 272 extend an extension depth D3 from a top surface of the source/drain region 232N to a bottom of the silicide region 272, the backside source/drain contact 315 and the silicide region 273 extend an extension depth D4 from a bottom surface of the source/drain region 232N to a top of the silicide region 273. In some embodiments, the extension depth D3 is an extension depth of the silicide region 272 in the source/drain region 232N. In some embodiments, the extension depth D4 is an extension depth of the silicide region 273 in the source/drain region 232N. The extension depth D4 is less than the extension depth D3. In some embodiments, a difference between the extension depths D3 and D4 ranges from about 3 nm to about 20 nm. In some embodiments, the extension depth D1 of the front-side source/drain contact 270 in the PFET region 203P is less than the extension depth D3 of the front-side source/drain contact 270 in the NFET region 203N. In some embodiments, a difference between the extension depths D1 and D3 ranges from about 2 nm to about 15 nm.

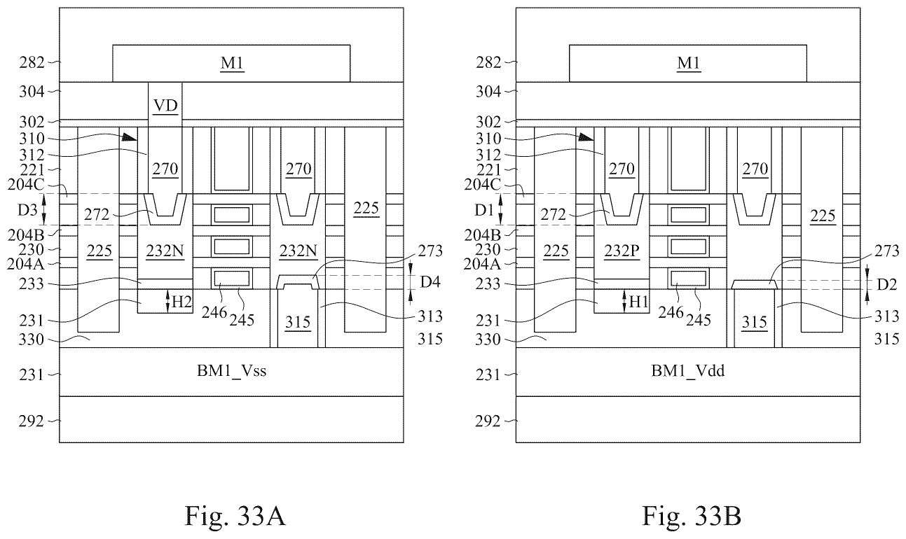

Reference is made to FIGS. 33A and 33B. FIGS. 33A and 33B illustrate cross-sectional views of a semiconductor structure, in accordance with some embodiments. FIG. 33A corresponds to the cross-section C1-C1′ of FIG. 31A. FIG. 33B corresponds to the cross-section C2-C2′ of FIG. 31A. As illustrated in FIGS. 33A and 33B, the semiconductor structure in FIGS. 33A and 33B is substantially the same as the semiconductor structure in FIGS. 32A and 32B, except that the extension depth D2 of the backside source/drain contact 315 in the PFET region 203P is reduced to near zero. In other words, the backside source/drain contact 315 in the PFET region 203P extends into the source/drain region 232P a little or just touches the bottom surface of the source/drain region 232P. In some embodiments, in the semiconductor structure as illustrated in FIGS. 33A and 33B, the bottom dielectric layers 231 are selectively formed and no bottom dielectric layer 231 is between the backside source/drain contact 315 and the source/drain region 232P in the PFET region 203P. In FIGS. 33A and 33B, the extension depth D2 of the backside source/drain contact 315 in the PFET region 203P is less than the extension depth D4 of the backside source/drain contact 315 in the NFET region 203N. In some embodiments, a difference between the extension depths D2 and D4 ranges from about 2 nm to about 15 nm.

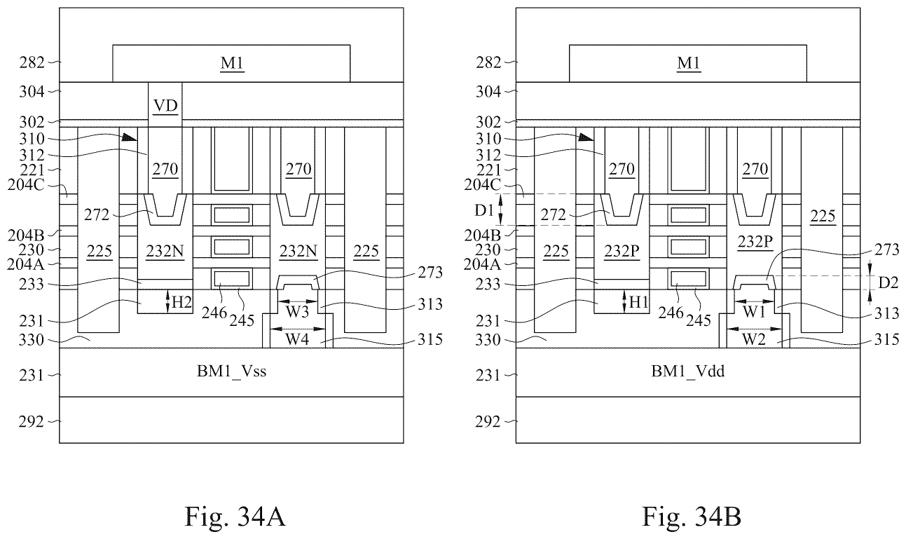

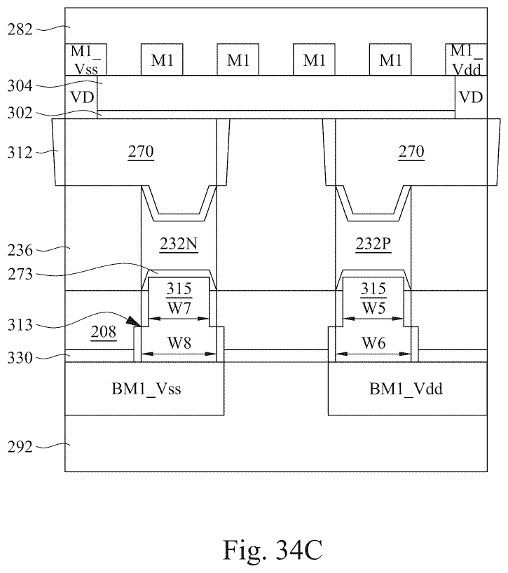

Reference is made to FIGS. 34A and 34B. FIGS. 34A and 34B illustrate cross-sectional views of a semiconductor structure, in accordance with some embodiments. FIG. 34A corresponds to the cross-section C1-C1′ of FIG. 31A. FIG. 34B corresponds to the cross-section C2-C2′ of FIG. 31A. As illustrated in FIGS. 34A and 34B, the semiconductor structure in FIGS. 34A and 34B may be substantially the same as the semiconductor structure in FIGS. 31B and 31C, except that the backside source/drain contacts 315 in the NFET region 203N and the PFET region 203P have different widths at different heights. In some embodiments, formation of the backside source/drain contacts 315 may include two-step etching. For example, formation of the backside source/drain contacts 315 includes forming a first trench in the ILD layer 330 and forming a second trench from a bottom of the first trench to the source/drain region 232, wherein the first trench is wider than the second trench. In some embodiments, the first trench with a wider width can be formed using the un-doped semiconductor layers 231 referred to as sacrificial layers. The etching of the first trench can stop at a bottom surface of the un-doped semiconductor layers 231 under the bottom dielectric layer 233. The etching of the second trench is then performed to etch the bottom dielectric layer 233 from a bottom of the first trench. In FIGS. 34A and 34B, the backside source/drain contact 315 in the PFET region 203P has a first portion connected to the silicide region 273 with a width W1 and a second portion under the first portion with a width W2, and the width W1 is less than the width W2. A top surface of the first portion of the backside source/drain contact 315 with the width W2 can be substantially level with a bottom surface of the un-doped semiconductor layer 231 in the PFET region 203P. In some embodiments, a ratio of the width W2 to the width W1 ranges from about 1.1 to about 3. The backside source/drain contact 315 in the NFET region 203N has a first portion connected to the silicide region 273 with a width W3 and a second portion under the first portion with a width W4, and the width W3 is less than the width W4. A top surface of the second portion of the backside source/drain contact 315 with the width W4 can be substantially level with a bottom surface of the un-doped semiconductor layer 231 in the NFET region 203N. In some embodiments, a ratio of the width W4 to the width W3 ranges from about 1.1 to about 3.

FIG. 34C illustrates a cross-sectional view of the semiconductor structure as illustrated in FIGS. 34A and 34B, in accordance with some embodiments. FIG. 34C corresponds to the cross-section C4-C4′ of FIG. 31A. As illustrated in FIG. 34C, the backside source/drain contacts 315 have different widths at different heights. In the cross-sectional view as illustrated in FIG. 34C, the backside source/drain contact 315 under the source/drain region 232P in the PFET region 203P has the first portion with the width W5 and the second portion under the first portion with a width W6, and the width W5 is less than the width W6. In some embodiments, a ratio of the width W6 to the width W5 ranges from about 1.1 to about 3. The backside source/drain contact 315 under the source/drain region 232N in the NFET region 203N has the first portion with the width W7 and the second portion under the first portion with a width W8, and the width W7 is less than the width W8. In some embodiments, a ratio of the width W8 to the width W7 ranges from about 1.1 to about 3.

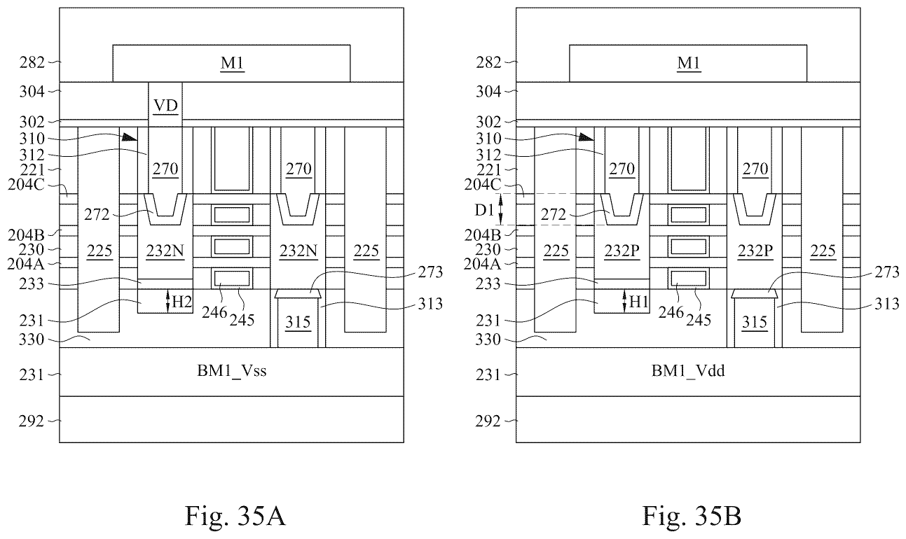

Reference is made to FIGS. 35A and 35B. FIGS. 35A and 35B illustrate cross-sectional views of a semiconductor structure, in accordance with some embodiments. FIG. 35A corresponds to the cross-section C1-C1′ of FIG. 31A. FIG. 35B corresponds to the cross-section C2-C2′ of FIG. 31A. As illustrated in FIGS. 35A and 35B, the semiconductor structure in FIGS. 35A and 35B is substantially the same as the semiconductor structure in FIGS. 33A and 33B, except that both of the backside source/drain contacts 315 just touch bottom surfaces of the source/drain regions 232N and 232P in the regions 203N and 203P. In some embodiments, in the semiconductor structure as illustrated in FIGS. 35A and 35B, the bottom dielectric layers 231 are selectively formed and no bottom dielectric layer 231 is between the backside source/drain contact 315 and the source/drain region 232N/232P. In some embodiments, top surfaces of the backside source/drain contact 315 are lower than bottom surfaces of the bottom dielectric layers 231.

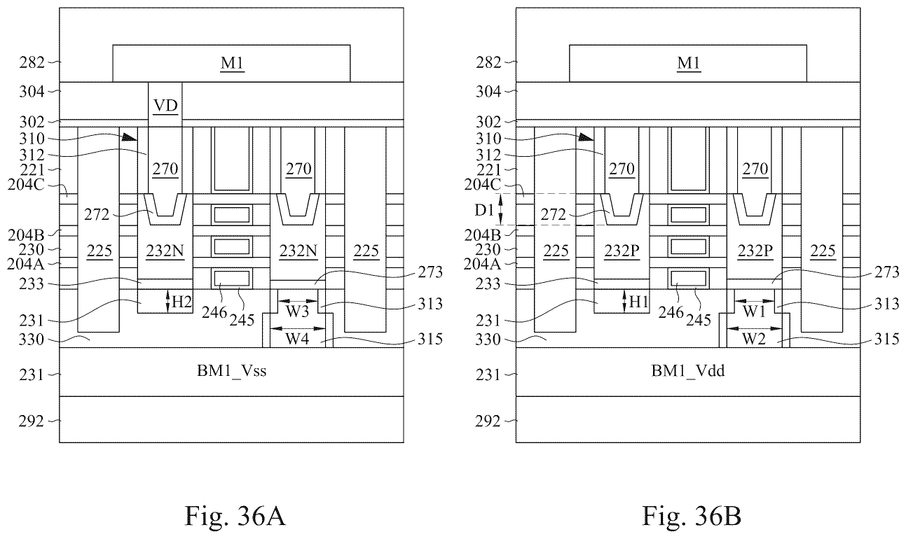

Reference is made to FIGS. 36A and 36B. FIGS. 36A and 36B illustrate cross-sectional views of a semiconductor structure, in accordance with some embodiments. FIG. 36A corresponds to the cross-section C1-C1′ of FIG. 31A. FIG. 36B corresponds to the cross-section C2-C2′ of FIG. 31A. As illustrated in FIGS. 36A and 36B, the semiconductor structure in FIGS. 36A and 36B is substantially the same as the semiconductor structure in FIGS. 34A and 34B, except that both of the backside source/drain contacts 315 just touch bottom surfaces of the source/drain regions 232N and 232P in the regions 203N and 203P. In some embodiments, in the semiconductor structure as illustrated in FIGS. 36A and 36B, the bottom dielectric layers 231 are selectively formed and no bottom dielectric layer 231 is between the backside source/drain contact 315 and the source/drain region 232N/232P. In some embodiments, top surfaces of the backside source/drain contact 315 are lower than bottom surfaces of the bottom dielectric layers 231.

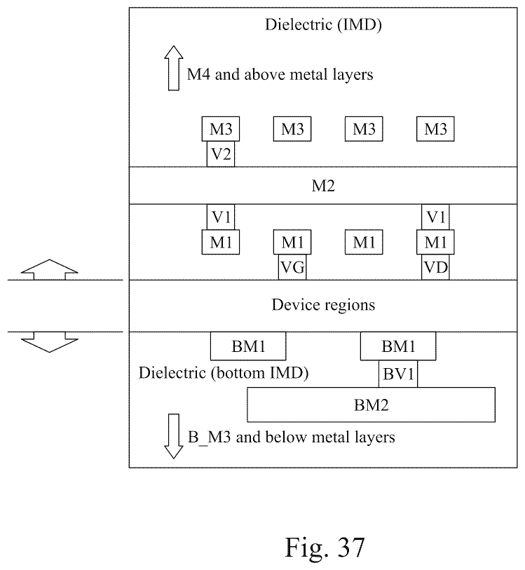

Reference is made to FIG. 37. FIG. 37 illustrates a schematic view of a semiconductor structure in accordance with some embodiments of the present disclosure. It is noted that FIG. 37 is schematically illustrated to show various levels of interconnect structure and transistors, and may not reflect the actual cross-sectional view of semiconductor structures. The semiconductor structure includes a device region including gate structures, nanostructures as channels and source/drain contacts, a contact level, an OD (wherein the term “OD” represents “active region”) level, via levels, such as gate via (VG) level and source/drain contact via (VD) level, via1 (V1) level, via2 (V2) level, via3 (V3) level and backside via1 (BV1) level, and metal-layer levels, such as M1 level, M2 level, M3 level, backside metal1 (BM1) level, and backside metal2 (BM2) level. Each of the illustrated levels includes one or more dielectric layers and the conductive features formed therein. The conductive features that are at the same level may have top surfaces substantially level to each other, bottom surfaces substantially level to each other, and may be formed simultaneously. The contact level may include gate vias (also referred to as contact plugs) for connecting gate electrodes of transistors (such as the illustrated exemplary transistors) to an overlying level such as the gate via level.

According to one or more embodiments of the present disclosure, a method includes a number of operations. An active region is formed over a substrate. A first source/drain feature and a second source/drain feature are formed over the active region. Interlayer dielectric (ILD) layers are over the first and second source/drain features. A gate structure is formed over the active region. A front-side source/drain contact is formed and extends in the ILD layer to electrically couple to the first source/drain feature. A front-side metal silicide layer is formed between the first source/drain feature and the front-side source/drain contact, wherein the front-side metal silicide layer includes a curved profile, wherein the front-side metal silicide layer vertically extends a first extension depth from a top surface of the first source/drain feature to a bottom of the front-side metal silicide layer. A backside source/drain contact is formed and extends from a backside of the substrate to electrically couple to the second source/drain feature. A backside metal silicide layer is formed between the second source/drain feature and the backside source/drain contact, wherein the backside metal silicide layer vertically extends a second extension depth from a bottom surface of the second source/drain feature to a top of the backside metal silicide layer, and wherein the second extension depth is less than the first extension depth. In one or more embodiments of the present disclosure, the method further includes forming bottom dielectric layers under the first and second source/drain features. In some embodiments, the second extension depth is zero so that a top surface of the backside source/drain contact is lower than a bottom surface of one of the bottom dielectric layers. In some embodiments, the method further includes forming un-doped semiconductor layers under the bottom dielectric layers. In one or more embodiments of the present disclosure, the backside metal silicide layer includes a curved profile. In one or more embodiments of the present disclosure, the method further includes forming an interface barrier layer between the front-side source/drain contact and the ILD layers. In one or more embodiments of the present disclosure, the method further includes forming a first metal line electrically coupled to the front-side source/drain contact and forming a second metal line electrically coupled to the backside source/drain contact. In one or more embodiments of the present disclosure, the backside source/drain contact includes a first portion with a first width and a second portion with a second width, the second portion is under the first portion, and the first width is less than the second width.

According to one or more embodiments of the present disclosure, a method includes a number of operations. A first transistor and a second transistor are formed over a substrate, wherein the first transistor includes a first epitaxial source/drain feature, and the second transistor includes a second epitaxial source/drain feature. Dielectric layers are formed over the first and second source/drain features. a front-side contact structure is formed and extends through the dielectric layer and across the first and second epitaxial source/drain features, wherein the front-side contact structure is surrounded by the dielectric layer, the front-side contact structure vertically extends a first extension depth from a top surface of the first source/drain feature to a bottom of the front-side contact structure in the first source/drain feature and a second extension depth from a top surface of the second source/drain feature to a bottom of the front-side contact structure in the second source/drain feature, and wherein the first extension depth is different from the second extension depth. A first backside contact structure is formed and electrically coupled to the first epitaxial source/drain feature of the first transistor from a backside of the substrate. A second backside contact structure is formed and electrically coupled to the second epitaxial source/drain feature of the second transistor from the backside of the substrate. In one or more embodiments of the present disclosure, the first transistor is an n-type transistor, the second transistor is a p-type transistor, and the second extension depth is less than the first extension depth. In one or more embodiments of the present disclosure, the first backside contact structure vertically extends a third extension depth from a bottom surface of the first epitaxial source/drain feature of the first transistor to a top surface of the first backside contact structure in the first epitaxial source/drain feature, the second backside contact structure vertically extends a fourth extension depth from a bottom surface of the second epitaxial source/drain feature of the first transistor to a top surface of the second backside contact structure in the second epitaxial source/drain feature, and the third extension depth is different from the fourth extension depth. In some embodiments, the first transistor is an n-type transistor, the second transistor is a p-type transistor, and the fourth extension depth is less than the third extension depth. In some embodiments, the fourth extension depth is less than the second extension depth. In one or more embodiments of the present disclosure, the method further includes forming bottom dielectric layers under the first and second epitaxial source/drain features. In some embodiments, the method further includes forming un-doped semiconductor layers under the bottom dielectric layers.

According to one or more embodiments of the present disclosure, a semiconductor structure includes a first transistor, a second transistor, a dielectric layer, a front-side contact feature and a first backside contact feature. The first transistor includes a first epitaxial source/drain feature. The second transistor includes a second epitaxial source/drain feature. The dielectric layer is disposed over the first and second epitaxial source/drain feature. The front-side contact feature extends through the dielectric layer and across the first and second epitaxial source/drain features. The front-side contact feature is surrounded by the dielectric layer. The contact feature is spaced apart from the dielectric layer by an interface layer. The front-side contact feature vertically extends a first extension depth from a top surface of the first epitaxial source/drain feature to a bottom of the front-side contact feature. The first backside contact feature extends from a backside of the first epitaxial source/drain feature of the first transistor. The first backside contact feature vertically extends a second extension depth from a bottom surface of the first epitaxial source/drain feature to a top of the first backside contact feature. The second extension depth is less than the first extension depth. In one or more embodiments of the present disclosure, the semiconductor structure further includes a second backside contact feature extending from a backside of the second epitaxial source/drain feature of the second transistor. The second backside contact feature vertically extends a third extension depth from a bottom surface of the second epitaxial source/drain feature to a top surface of the second backside contact feature. The third extension depth is different from the second extension depth. In one or more embodiments of the present disclosure, the semiconductor structure further includes a plurality of bottom dielectric layers under the first and second epitaxial source/drain features. In some embodiments, the semiconductor structure further includes a plurality of un-doped semiconductor layer under the bottom dielectric layers. In some embodiments, the first and second transistors are on a substrate. A material of the un-doped semiconductor layers is different from a material of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an active region over a substrate;
forming a first source/drain feature and a second source/drain feature over the active region;
forming interlayer dielectric (ILD) layers over the first and second source/drain features;
forming a gate structure over the active region;
forming a front-side source/drain contact extending in the ILD layer to electrically couple to the first source/drain feature;
forming a front-side metal silicide layer between the first source/drain feature and the front-side source/drain contact, wherein the front-side metal silicide layer comprises a curved profile, wherein the front-side metal silicide layer vertically extends a first extension depth from a top surface of the first source/drain feature to a bottom of the front-side metal silicide layer;
forming a backside source/drain contact extending from a backside of the substrate to electrically couple to the second source/drain feature; and
forming a backside metal silicide layer between the second source/drain feature and the backside source/drain contact, wherein the backside metal silicide layer vertically extends a second extension depth from a bottom surface of the second source/drain feature to a top of the backside metal silicide layer, and wherein the second extension depth is less than the first extension depth.

2. The method of claim 1, further comprising:
forming bottom dielectric layers under the first and second source/drain features.

3. The method of claim 2, wherein the second extension depth is zero so that a top surface of the backside source/drain contact is lower than a bottom surface of one of the bottom dielectric layers.

4. The method of claim 2, further comprising:
forming un-doped semiconductor layers under the bottom dielectric layers.

5. The method of claim 1, wherein the backside metal silicide layer comprises a curved profile.

6. The method of claim 1, further comprising:
forming an interface barrier layer between the front-side source/drain contact and the ILD layers.

7. The method of claim 1, further comprising:
forming a first metal line electrically coupled to the front-side source/drain contact; and
forming a second metal line electrically coupled to the backside source/drain contact.

8. The method of claim 1, wherein the backside source/drain contact comprises a first portion with a first width and a second portion with a second width, the second portion is under the first portion, and the first width is less than the second width.

9. A method comprising:
forming a first transistor and a second transistor over a substrate, wherein the first transistor comprises a first epitaxial source/drain feature, and the second transistor comprises a second epitaxial source/drain feature;
forming dielectric layers over the first and second source/drain features;
forming a front-side contact structure extending through the dielectric layer and across the first and second epitaxial source/drain features, wherein the front-side contact structure is surrounded by the dielectric layer, the front-side contact structure vertically extends a first extension depth from a top surface of the first source/drain feature to a bottom of the front-side contact structure in the first source/drain feature and a second extension depth from a top surface of the second source/drain feature to a bottom of the front-side contact structure in the second source/drain feature, and wherein the first extension depth is different from the second extension depth;
forming a first backside contact structure electrically coupled to the first epitaxial source/drain feature of the first transistor from a backside of the substrate; and
forming a second backside contact structure electrically coupled to the second epitaxial source/drain feature of the second transistor from the backside of the substrate.

10. The method of claim 9, wherein the first transistor is an n-type transistor, the second transistor is a p-type transistor, and the second extension depth is less than the first extension depth.

11. The method of claim 9, wherein the first backside contact structure vertically extends a third extension depth from a bottom surface of the first epitaxial source/drain feature of the first transistor to a top surface of the first backside contact structure in the first epitaxial source/drain feature, the second backside contact structure vertically extends a fourth extension depth from a bottom surface of the second epitaxial source/drain feature of the first transistor to a top surface of the second backside contact structure in the second epitaxial source/drain feature, and the third extension depth is different from the fourth extension depth.

12. The method of claim 11, wherein the first transistor is an n-type transistor, the second transistor is a p-type transistor, and the fourth extension depth is less than the third extension depth.

13. The method of claim 11, wherein the fourth extension depth is less than the second extension depth.

14. The method of claim 9, further comprising:
forming bottom dielectric layers under the first and second epitaxial source/drain features.

15. The method of claim 14, further comprising:
forming un-doped semiconductor layers under the bottom dielectric layers.

16. A semiconductor structure comprising:
a first transistor comprising a first epitaxial source/drain feature;
a second transistor comprising a second epitaxial source/drain feature;
a dielectric layer disposed over the first and second epitaxial source/drain feature;
a front-side contact feature extending through the dielectric layer and across the first and second epitaxial source/drain features, wherein the front-side contact feature is surrounded by the dielectric layer, the contact feature is spaced apart from the dielectric layer by an interface layer, and wherein the front-side contact feature vertically extends a first extension depth from a top surface of the first epitaxial source/drain feature to a bottom of the front-side contact feature; and
a first backside contact feature extending from a backside of the first epitaxial source/drain feature of the first transistor, wherein the first backside contact feature vertically extends a second extension depth from a bottom surface of the first epitaxial source/drain feature to a top of the first backside contact feature, and wherein the second extension depth is less than the first extension depth.

17. The semiconductor structure of claim 16, further comprising:
a second backside contact feature extending from a backside of the second epitaxial source/drain feature of the second transistor, wherein the second backside contact feature vertically extends a third extension depth from a bottom surface of the second epitaxial source/drain feature to a top surface of the second backside contact feature, and wherein the third extension depth is different from the second extension depth.

18. The semiconductor structure of claim 16, further comprising:
a plurality of bottom dielectric layers under the first and second epitaxial source/drain features.

19. The semiconductor structure of claim 18, further comprising:
a plurality of un-doped semiconductor layer under the bottom dielectric layers.

20. The semiconductor structure of claim 19, wherein the first and second transistors are on a substrate, and a material of the un-doped semiconductor layers is different from a material of the substrate.
